(19) United States
(12) Patent Application Publication
(10) Pub. No.: US 2026/0352170 A1
(43) Pub. Date: Nov. 5, 2026

(54) APPARATUS, SYSTEM, AND METHOD OF A DIGITAL POWER AMPLIFIER

(71) Applicant: INTEL CORPORATION, Santa Clara, CA (US)

(72) Inventors: Ofir DEGANI, Nes-Ammin (IL); Naor Roi SHAY, Rehovot (IL); Assaf BEN-BASSAT, Haifa (IL); Yuri ROZENFELD, Haifa (IL)

(73) Assignee: INTEL CORPORATION, Santa Clara, CA (US)

(21) Appl. No.: 19/482,760

(22) PCT Filed: Dec. 28, 2023
(86) PCT No.: PCT/US2023/086296

§ 371 Date: Nov. 9, 2025

Related U.S. Application Data
(60) Provisional application No. 63/507,663, filed on Jun. 12, 2023.

(51) Int. Cl. H03F 3/24; H03F 1/02; H03F 3/195; H03F 3/213; H03F 3/45; H03K 19/0175

(52) U.S. Cl. CPC H03F 3/245; H03F 1/0211; H03F 3/195; H03F 3/213; H03F 3/45264; H03K 19/017509; H03F 2200/451

(57) ABSTRACT

For example, a Digital Power Amplifier (PA) (DPA) may include a dual Level Shifter (LS) configured to generate a differential LS output based on a differential input signal including a negative input signal and a positive input signal. The dual LS may include a first LS to provide a first single-ended LS output including a first LS output based on a first input signal, which is based on the negative input signal; and a second LS to provide a second single-ended LS output including a second LS output based on a second input signal, which is based on the positive input signal. The DPA may include first PA circuitry to generate a first PA signal based on the first LS output, and second PA circuitry to generate a second PA signal based on the second LS output.

### CROSS REFERENCE

This Application claims the benefit of and priority from U.S. Provisional Patent Application No. 63/507,663 entitled “APPARATUS, SYSTEM, AND METHOD OF A POWER AMPLIFIER”, filed Jun. 12, 2023, the entire disclosure of which is incorporated herein by reference.

### BACKGROUND

A power amplifier may be configured to amplify an input signal.

For example, the power amplifier may be implemented as part of a transmitter to amplify a signal to be transmitted.

### BRIEF DESCRIPTION OF THE DRAWINGS

For simplicity and clarity of illustration, elements shown in the figures have not necessarily been drawn to scale. For example, the dimensions of some of the elements may be exaggerated relative to other elements for clarity of presentation. Furthermore, reference numerals may be repeated among the figures to indicate corresponding or analogous elements. The figures are listed below.

FIG. 1 is a schematic block diagram illustration of an apparatus, in accordance with some demonstrative aspects.

FIGS. 2A, 2B, 2C, and 2D are schematic illustrations of a single-mode power amplifier with a single Level Shifter (LS) to illustrate one or more technical issues, which may be addressed in accordance with some demonstrative aspects.

FIGS. 3A, 3B, 3C, 3D, and 3E are schematic illustrations of a multi-mode power amplifier with a single LS to illustrate one or more technical issues, which may be addressed in accordance with some demonstrative aspects.

FIGS. 4A, 4B, 4C, 4D, and 4E are schematic illustrations of a single-mode Digital Power Amplifier (DPA) with a dual LS, in accordance with some demonstrative aspects.

FIGS. 5A, 5B, 5C, 5D, 5E, and 5F are schematic illustrations of a dual-mode DPA with a dual LS, in accordance with some demonstrative aspects.

FIG. 6 is a schematic illustration of a graph depicting simulated Power Added Efficiency (PAE) results versus output power, in accordance with some demonstrative aspects.

FIG. 7 is a schematic illustration of a communication device, in accordance with some demonstrative aspects.

FIG. 8 is a schematic flow-chart illustration of a method of a DPA, in accordance with some demonstrative aspects.

FIG. 9 is a schematic illustration of a product of manufacture, in accordance with some demonstrative aspects.

### DETAILED DESCRIPTION

In the following detailed description, numerous specific details are set forth in order to provide a thorough understanding of some aspects. However, it will be understood by persons of ordinary skill in the art that some aspects may be practiced without these specific details. In other instances, well-known methods, procedures, components, units and/or circuits have not been described in detail so as not to obscure the discussion.

Discussions herein utilizing terms such as, for example, “processing”, “computing”, “calculating”, “determining”, “establishing”, “analyzing”, “checking”, or the like, may refer to operation(s) and/or process(es) of a computer, a computing platform, a computing system, or other electronic computing device, that manipulate and/or transform data represented as physical (e.g., electronic) quantities within the computer's registers and/or memories into other data similarly represented as physical quantities within the computer's registers and/or memories or other information storage medium that may store instructions to perform operations and/or processes.

The terms “plurality” and “a plurality”, as used herein, include, for example, “multiple” or “two or more”. For example, “a plurality of items” includes two or more items.

References to “one aspect”, “an aspect”, “demonstrative aspect”, “various aspects” etc., indicate that the aspect(s) so described may include a particular feature, structure, or characteristic, but not every aspect necessarily includes the particular feature, structure, or characteristic. Further, repeated use of the phrase “in one aspect” does not necessarily refer to the same aspect, although it may.

As used herein, unless otherwise specified the use of the ordinal adjectives “first”, “second”, “third” etc., to describe a common object, merely indicate that different instances of like objects are being referred to, and are not intended to imply that the objects so described must be in a given sequence, either temporally, spatially, in ranking, or in any other manner.

Some aspects may be used in conjunction with various devices and systems, for example, a User Equipment (UE), a Mobile Device (MD), a wireless station (STA), a Personal Computer (PC), a desktop computer, a mobile computer, a laptop computer, a notebook computer, a tablet computer, a server computer, a handheld computer, a handheld device, a wearable device, a sensor device, an Internet of Things (IoT) device, a Bluetooth (BT) device, a Bluetooth Low Energy (BLE) device, an audio device, a video device, an audio (A/V) device, a Personal Digital Assistant (PDA) device, a handheld PDA device, an on-board device, an off-board device, a hybrid device, a vehicular device, a non-vehicular device, a mobile or portable device, a consumer device, a non-mobile or non-portable device, a wireless communication station, a wireless communication device, a wired or wireless network, a wireless area network, a Wireless Video Area Network (WVAN), a Local Area Network (LAN), a Wireless LAN (WLAN), a Personal Area Network (PAN), a Wireless PAN (WPAN), and the like.

Some aspects may be used in conjunction with devices and/or networks operating in accordance with existing IEEE 802.11 standards (including IEEE 802.11-2020 (IEEE 802.11-2020, IEEE Standard for Information Technology—Telecommunications and Information Exchange between Systems Local and Metropolitan Area Networks—Specific Requirements; Part 11: Wireless LAN Medium Access Control (MAC) and Physical Layer (PHY) Specifications, December, 2020), and/or future versions and/or derivatives thereof, devices and/or networks operating in accordance with existing cellular specifications and/or protocols, units and/or devices which are part of the above networks, and the like.

Some aspects may be used in conjunction with one way and/or two-way radio communication systems, wireless communication systems, cellular radio-telephone communication systems, a mobile phone, a cellular telephone, a wireless telephone, a Bluetooth system, a Personal Communication Systems (PCS) device, a PDA device which incorporates a wireless communication device, a mobile or portable Global Positioning System (GPS) device, a device which incorporates a GPS receiver or transceiver or chip, a device which incorporates an RFID element or chip, a Multiple Input Multiple Output (MIMO) transceiver or device, a Single Input Multiple Output (SIMO) transceiver or device, a Multiple Input Single Output (MISO) transceiver or device, a device having one or more internal antennas and/or external antennas, Digital Video Broadcast (DVB) devices or systems, multi-standard radio devices or systems, a wired or wireless handheld device, e.g., a Smartphone, a Wireless Application Protocol (WAP) device, or the like.

Some aspects may be used in conjunction with one or more types of wireless communication signals and/or systems, for example, Radio Frequency (RF), Infra-Red (IR), Frequency-Division Multiplexing (FDM), Orthogonal FDM (OFDM), Orthogonal Frequency-Division Multiple Access (OFDMA), Time-Division Multiplexing (TDM), Time-Division Multiple Access (TDMA), Multi-User MIMO (MU-MIMO), Spatial Division Multiple Access (SDMA), Extended TDMA (E-TDMA), General Packet Radio Service (GPRS), Extended GPRS, Code-Division Multiple Access (CDMA), Wideband CDMA (WCDMA), CDMA 2000, single-carrier CDMA, multi-carrier CDMA, Multi-Carrier Modulation (MCM), Discrete Multi-Tone (DMT), Bluetooth®, Global Positioning System (GPS), Wi-Fi, Wi-Max, ZigBee™, Ultra-Wideband (UWB), Global System for Mobile communication (GSM), 2G, 2.5G, 3G, 3.5G, 4G, Fifth Generation (5G), or Sixth Generation (6G) mobile networks, 3GPP, Long Term Evolution (LTE), LTE Advanced, Enhanced Data rates for GSM Evolution (EDGE), or the like. Other aspects may be used in various other devices, systems and/or networks.

The term “wireless device”, as used herein, includes, for example, a device capable of wireless communication, a communication device capable of wireless communication, a communication station capable of wireless communication, a portable or non-portable device capable of wireless communication, or the like. In some demonstrative aspects, a wireless device may be or may include a peripheral that is integrated with a computer, or a peripheral that is attached to a computer. In some demonstrative aspects, the term “wireless device” may optionally include a wireless service.

The term “communicating” as used herein with respect to a communication signal includes transmitting the communication signal and/or receiving the communication signal. For example, a communication unit, which is capable of communicating a communication signal, may include a transmitter to transmit the communication signal to at least one other communication unit, and/or a communication receiver to receive the communication signal from at least one other communication unit. The verb communicating may be used to refer to the action of transmitting or the action of receiving. In one example, the phrase “communicating a signal” may refer to the action of transmitting the signal by a first device, and may not necessarily include the action of receiving the signal by a second device. In another example, the phrase “communicating a signal” may refer to the action of receiving the signal by a first device, and may not necessarily include the action of transmitting the signal by a second device. The communication signal may be transmitted and/or received, for example, in the form of Radio Frequency (RF) communication signals, and/or any other type of signal.

As used herein, the term “circuitry” may refer to, be part of, or include, an Application Specific Integrated Circuit (ASIC), an integrated circuit, an electronic circuit, a processor (shared, dedicated, or group), and/or memory (shared, dedicated, or group), that execute one or more software or firmware programs, a combinational logic circuit, and/or other suitable hardware components that provide the described functionality. In some aspects, some functions associated with the circuitry may be implemented by, one or more software or firmware modules. In some aspects, circuitry may include logic, at least partially operable in hardware.

The term “logic” may refer, for example, to computing logic embedded in circuitry of a computing apparatus and/or computing logic stored in a memory of a computing apparatus. For example, the logic may be accessible by a processor of the computing apparatus to execute the computing logic to perform computing functions and/or operations. In one example, logic may be embedded in various types of memory and/or firmware, e.g., silicon blocks of various chips and/or processors. Logic may be included in, and/or implemented as part of, various circuitry, e.g. radio circuitry, receiver circuitry, control circuitry, transmitter circuitry, transceiver circuitry, processor circuitry, and/or the like. In one example, logic may be embedded in volatile memory and/or non-volatile memory, including random access memory, read only memory, programmable memory, magnetic memory, flash memory, persistent memory, and the like. Logic may be executed by one or more processors using memory, e.g., registers, stuck, buffers, and/or the like, coupled to the one or more processors, e.g., as necessary to execute the logic.

Some demonstrative aspects may be used in conjunction with a WLAN, e.g., a WiFi network, and/or a cellular network, e.g., a 5G network. Other aspects may be used in conjunction with any other suitable wireless communication network, for example, a wireless area network, a “piconet”, a WPAN, a WVAN, and the like.

Some demonstrative aspects may be used in conjunction with a wireless communication network communicating over a frequency band of 2.4 GHz, 5 GHz, or 6 GHz. However, other aspects may be implemented utilizing any other suitable wireless communication frequency bands, for example, an Extremely High Frequency (EHF) band (the millimeter wave (mmWave) frequency band), e.g., a frequency band within the frequency band of between 20 GHz and 300 GHz, a WLAN frequency band, a WPAN frequency band, and the like.

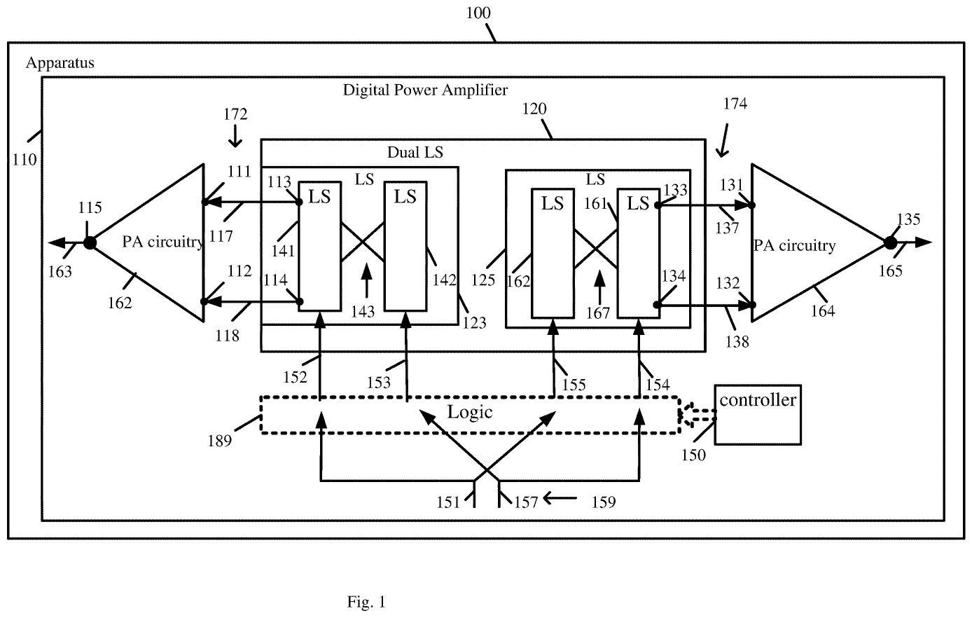

Reference is made to FIG. 1, which schematically illustrates an apparatus 100, in accordance with some demonstrative aspects.

In some demonstrative aspects, apparatus 100 may be implemented as part of a communication device, e.g., as described below.

In some demonstrative aspects, apparatus 100 may be implemented as part of a communication interface, e.g., as described below.

In some demonstrative aspects, apparatus 100 may be implemented as part of a transmitter, e.g., as described below.

In other aspects, apparatus 100 may be implemented as part of any other device, element and/or component, e.g., as described below.

In some demonstrative aspects, apparatus 100 may include a Power Amplifier (PA) 110, e.g., as described below.

In some demonstrative aspects, PA 110 may include a Digital PA (DPA) 110, e.g., as described below.

In some demonstrative aspects, DPA 110 may be configured to amplify an input signal into an output signal.

In some demonstrative aspects, PA 110 may include a single-mode PA, e.g., a single-mode DPA, which may be configured to amplify the input signal at a single power mode, e.g., as described below.

In some demonstrative aspects, PA 110 may include a multi-mode PA, for example, a multi-mode DPA, which may be configured to amplify an input signal at a plurality of power modes, e.g., as described below.

In one example, the plurality of power modes may include a high output power mode, a low output power mode, and/or any other additional or alternative power modes.

In some demonstrative aspects, the multi-mode PA may be configured to provide a technical solution to support the plurality of power modes, for example, while keeping high efficiency, e.g., for some or all of the plurality of power modes.

In some demonstrative aspects, the multi-mode PA may be configured to provide a technical solution to support a plurality of power modes corresponding to a plurality of wireless communication interfaces, e.g., as described below.

In some demonstrative aspects, the multi-mode PA may be configured to provide a technical solution to support a first power mode corresponding to a first wireless communication interface utilizing a first wireless communication technology, e.g., Bluetooth; and to support a second power mode corresponding to a second wireless communication interface utilizing a second wireless communication technology, e.g., WiFi, e.g., as described below.

In one example, the multi-mode PA may be configured to support a BT power mode for BT communications, and a WiFi power mode for WiFi communications. For example, the multi-mode PA may be configured to provide a technical solution to support the BT power mode and the WiFi power mode on a same core, for example, while keeping high efficiency for both power modes. For example, the BT power mode may be configured to provide a power level of milliwatts (mW), e.g., a maximal power (Pmax) of about 600 mW (18-20 dBm) and/or any other power level. For example, the WiFi power mode may be configured to provide a power level of about one Watt, e.g., Pmax~0.5-1 W (28-30 dBm), and/or any other power level.

In some demonstrative aspects, a DPA, e.g., DPA 110, may be implemented as part of a Digital Tx (DTX) architecture. For example, DTX architectures may be implemented to provide a technical solution for a wireless communication transceiver (TRX), for example, while utilizing one or more technical advantages, e.g., in terms of compact die area, scalability in advanced CMOS processes, and/or improved power efficiency of the DPAs.

In some demonstrative aspects, a DPA, e.g., DPA 110, may be configured according to a high-voltage switched capacitor DPA topology. For example, the high-voltage switched capacitor DPA topology may be configured based on triple stack floating gate feedback, or even using a higher number of devices. For example, the high-voltage switched capacitor DPA topology may be configured to provide a technical solution to support higher transmit power levels, improved memory effects, e.g., due to lower current consumption, an ability to withstand reliability considerations, and/or any other additional and/or alternative technical advantages.

In some demonstrative aspects, in some use cases, and/or implementations there may be a need to address one or more technical issues of high-voltage switched capacitor DPA topologies. For example, the high-voltage switched capacitor DPA topology may suffer leakage, e.g., during an off-state of the DPA. For example, in some implementations, a DPA may be connected directly to a main supply voltage, and, accordingly, it may be difficult to ensure that this main supply voltage may be a switchable power domain. For example, adding an additional power switch for this main supply voltage may result in dynamic affects, e.g., due to additional ohmic (IR) drops, and/or due to cost of a Direct Current (DC) switch, which may be added to a product.

In some demonstrative aspects, in some use cases, and/or scenarios, there may be one or more technical inefficiencies, disadvantages and/or problems in implementing multiple, e.g., 2, 4 or more, core power combining techniques, for example, to achieve higher power working from DC-to-DC (DC2DC).

In some demonstrative aspects, in some use cases, and/or scenarios, there may be one or more technical inefficiencies, disadvantages and/or problems in implementing a DPA according to a high-voltage switched capacitor DPA topology utilizing a single Level Shifter (LS), e.g., as described below.

For example, some implementations may require using an external/internal power switch on a main supply rail of the DPA, which may result in increase in cost and/or area.

For example, in some use cases and/or implementations, a Modulated Local Oscillator (MOLO) clock leakage to an output of the DPA may occur, for example, during a low power transmitter mode, which may not be optimal, e.g., due to supply ripple coupling.

For example, in some use cases and/or implementations, there may be higher dynamic affects during transmission, for example, by applying supply to the DPA through an external or internal DC Switch.

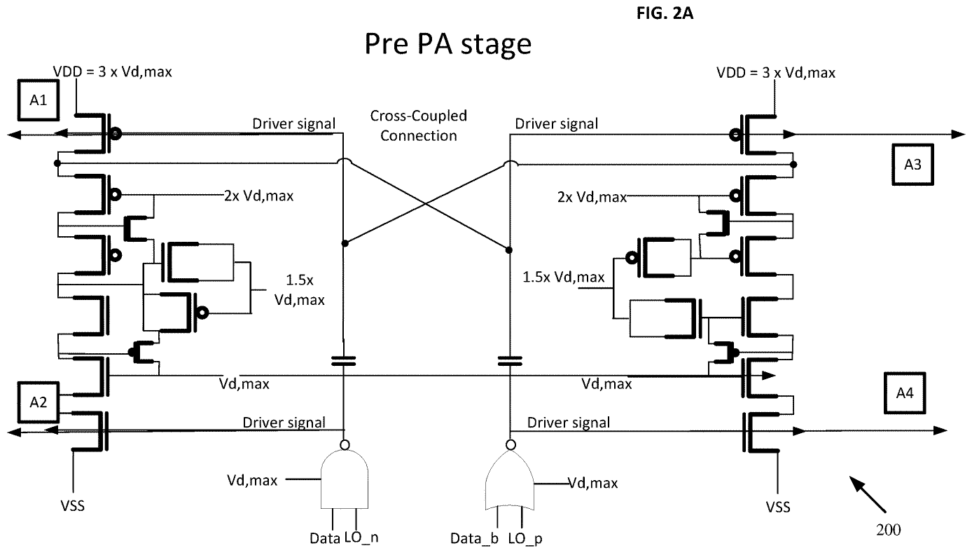

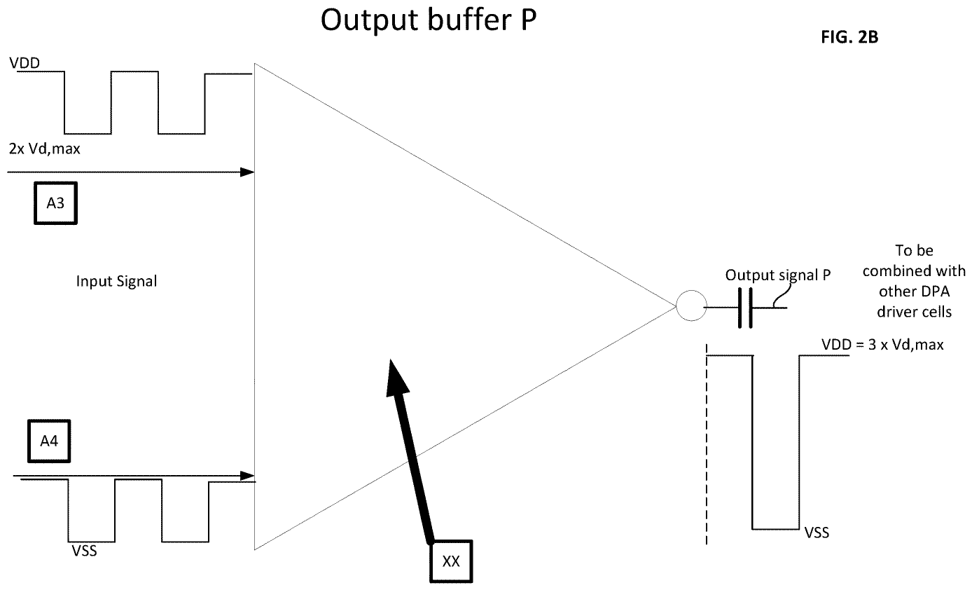

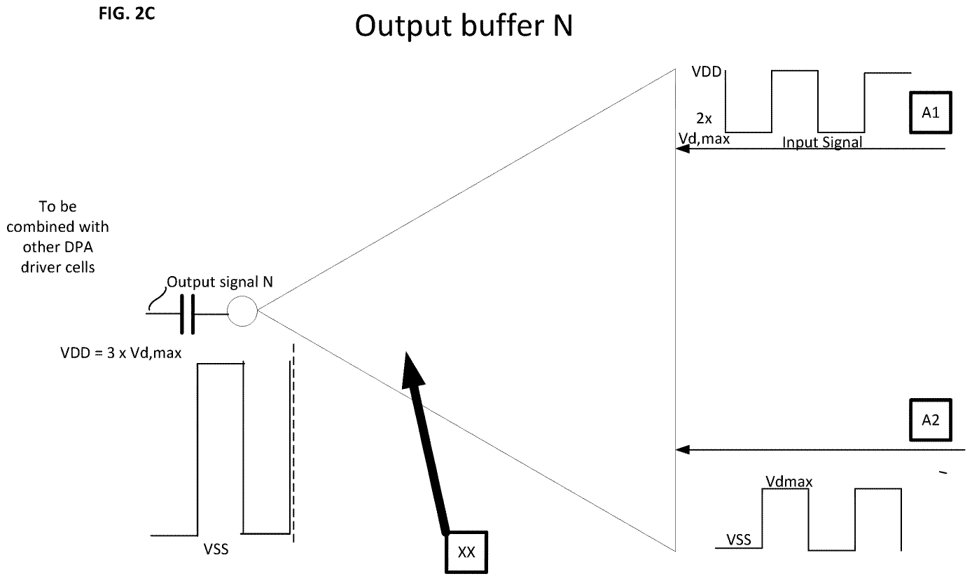

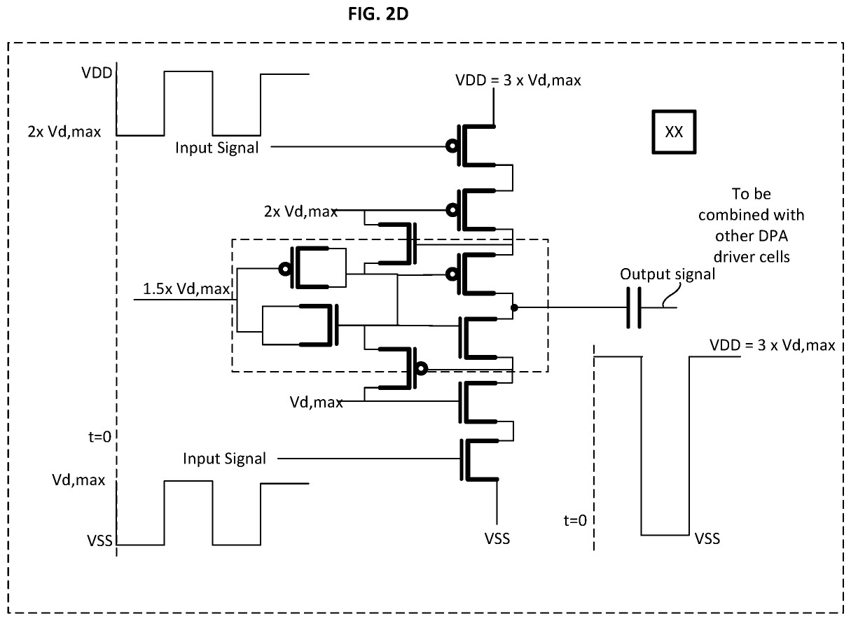

Reference is made to FIGS. 2A, 2B, 2C, and 2D, which schematically illustrate a single-mode DPA cell with a single LS 200 to illustrate one or more technical issues, which may be addressed in accordance with some demonstrative aspects.

For example, FIG. 2A illustrates circuitry of the single LS 200.

For example, FIG. 2B illustrates a first PA output stage (“output buffer P”) of the multi-mode DPA.

For example, FIG. 2C illustrates a second PA output stage (“output buffer N”) of the multi-mode DPA.

For example, FIG. 2D illustrates PA output stage circuitry, which may be implemented by the first PA output stage of FIG. 2B and/or the second PA output stage of FIG. 2C.

For example, the single-mode DPA of FIGS. 2A-2D may be configured to use a Drain Voltage (VDD) of VDD=3×Vdmax in 3 stacked devices with a single LS architecture, e.g., the single LS 200, for example, to provide a single mode architecture with a switchable supply.

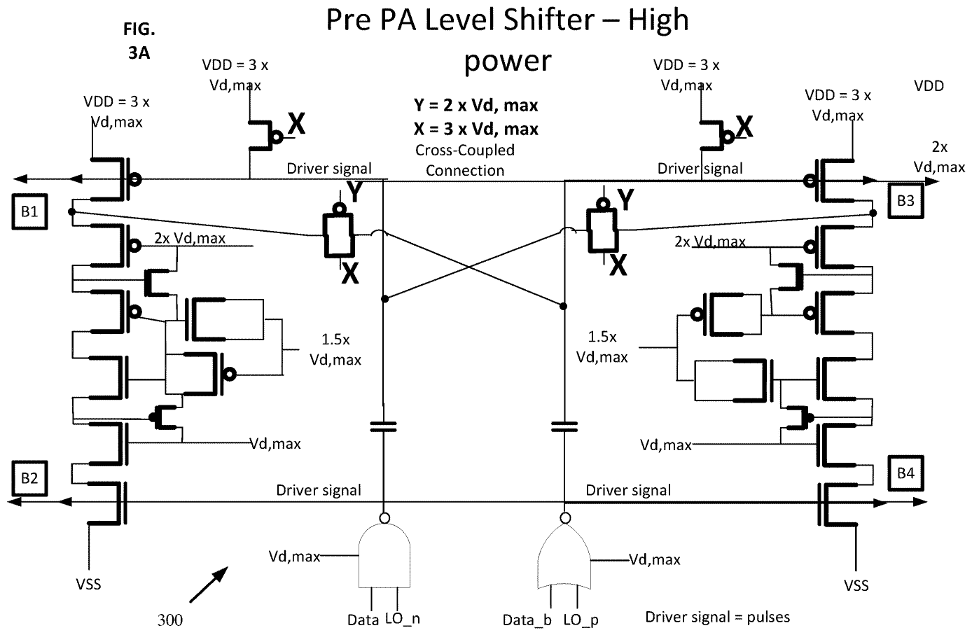

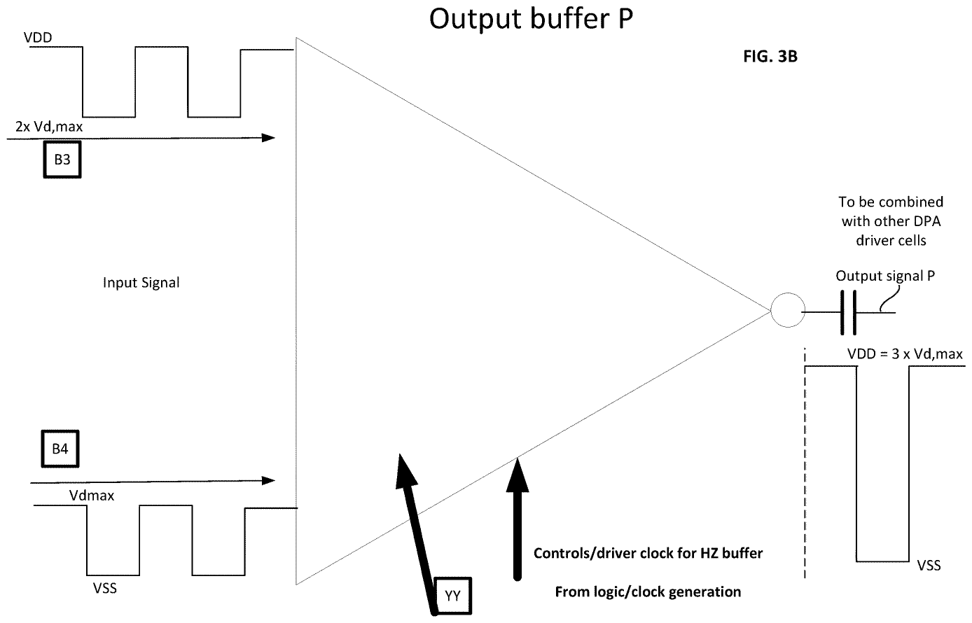

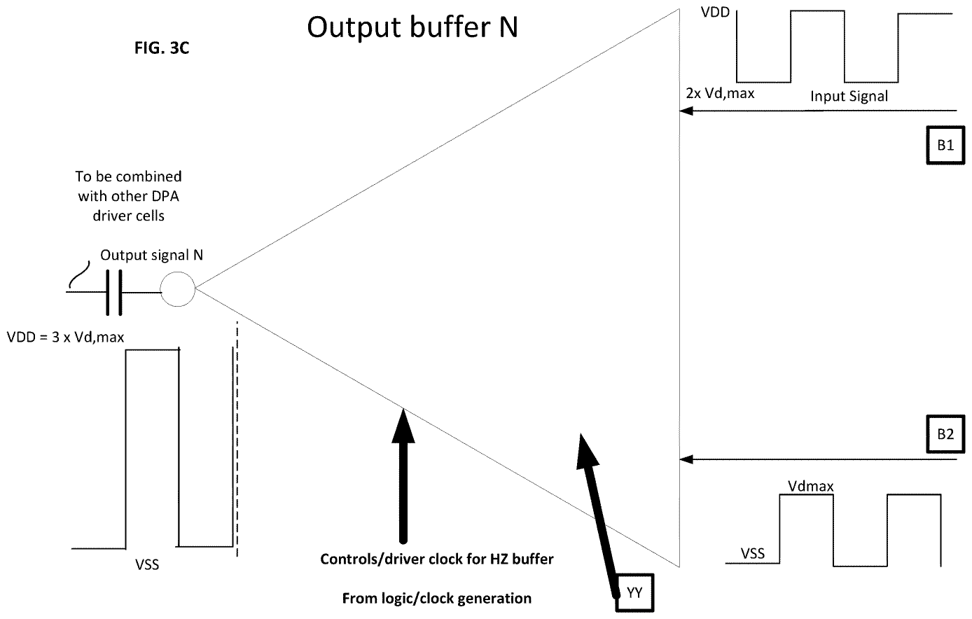

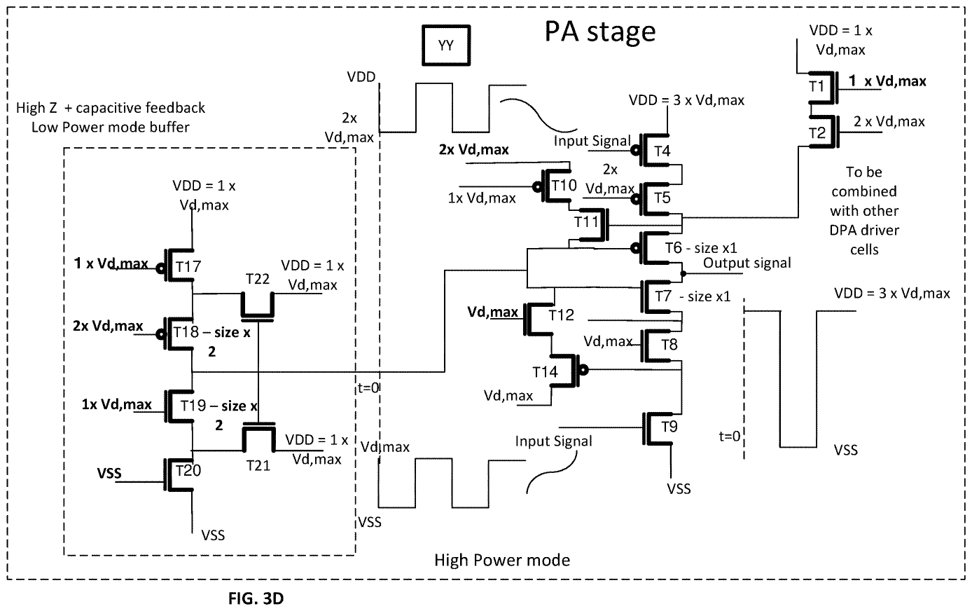

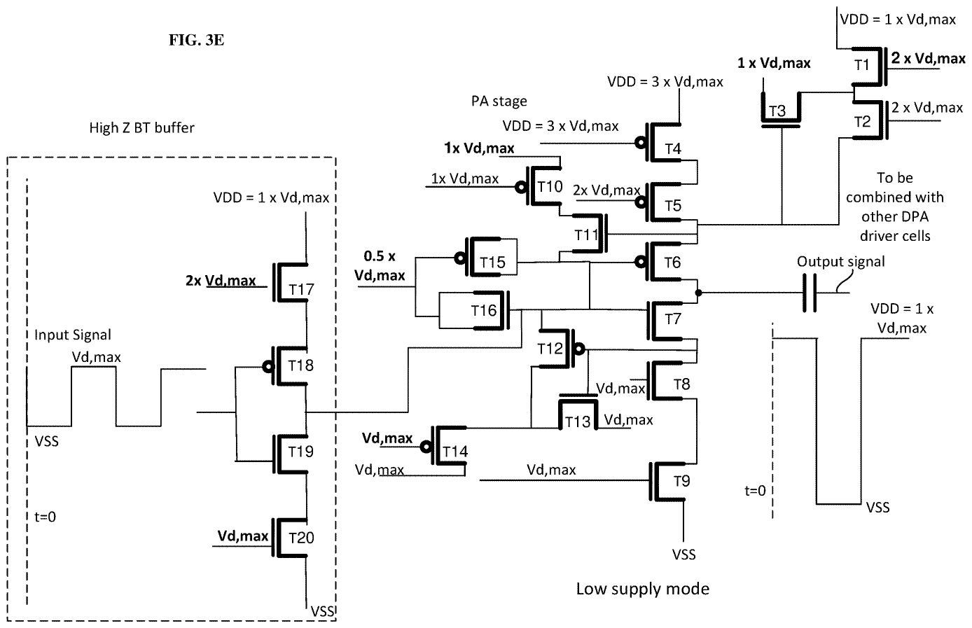

Reference is made to FIGS. 3A, 3B, 3C, 3D and 3E, which schematically illustrate a multi-mode, e.g., dual mode/Class G, DPA cell with a single LS 300 to illustrate one or more technical issues, which may be addressed in accordance with some demonstrative aspects.

For example, FIG. 3A illustrates circuitry of the single LS 300 operable at a high-supply mode of the multi-mode DPA.

For example, FIG. 3B illustrates a first PA output stage (output buffer P) of the multi-mode DPA.

For example, FIG. 3C illustrates a second PA output stage (output buffer N) of the multi-mode DPA.

For example, FIG. 3D illustrates PA output stage circuitry operable at a high-supply mode of the dual-mode/Class G DPA cell.

For example, FIG. 3E illustrates the PA output stage circuitry operable at a low-supply mode of the dual-mode/Class G DPA cell.

For example, as shown in FIGS. 3B and 3C, the PA output stage circuitry of FIGS. 3D and/or 3E may be implemented as part of the first PA output stage (FIG. 3B) and/or the second PA output stage (FIG. 3C).

For example, the multi-mode power amplifier of FIGS. 3A-3E may be configured to use a VDD of VDD=3×Vdmax in 3 stacked devices with a single LS architecture, e.g., the single LS 300, for example, for a dual mode/class G operation with switchable supply.

For example, in some use cases and/or implementations, some power amplifier architectures, e.g., power amplifier architectures utilizing the single LS of power amplifier architectures of FIGS. 2A-2D and/or 3A-3E, may suffer from a Gate Induced drain Leakage (GIDL) leakage phenomenon. For example, leakage in the multi-device stacking may occur in N-channel Metal-Oxide Semiconductor (NMOS) devices in advance nodes, for example, due to high fields applied between a gate node and drain/source nodes of the NMOS devices, for example, during an off-state.

For example, in some use cases and/or implementations, there may be a technical issue, for example, when using the dual mode/Class G architecture of FIGS. 3A-3E with a single LS. For example, for the low supply mode of operation there may be need to disconnect an output stage high supply branch and work from a low supply branch of the output stage. For example, in order to achieve switching between the low and high supply modes, the outputs of the single level shifter may be pulled-up, for example, to ensure the high supply mode branch of the output stage is turned off, for example, during the low supply mode.

For example, the high supply mode of the output stage of the dual-mode output buffer is shown in FIG. 3D.

For example, the low supply mode of the output stage of the dual-mode output buffer is shown in FIG. 3E.

For example, in some use cases and/or implementations, an input clock signal may pass through one or more logical gates, for example, a NOR gate or a NAND gate, and may be transformed, e.g., through the single level shifter, into a differential LS output, e.g., including an output negative (N) driver signal and a positive (P) driver signal.

For example, during the off-state, the input clock (clk) may be turned off, and the outputs of the NOR gate the NAND gate may apply 1 and 0 for their outputs, respectively.

For example, this setting may apply, for example, for the output buffer N a combination of [NMOS,PMOS]=[0, 2×Vdmax], and for the output buffer P a combination of [NMOS,PMOS]=[1×Vdmax, 3×Vdmax].

For example, one output cap may hold 0V, which may lead to 3×Vdmax being applied on the 3 PMOS devices, e.g., as the VDD, while the other output cap may hold 3×Vdmax, which may lead to 3×Vdmax applied on the 3 NMOS devices, e.g., as the VDD.

For example, this situation may result in leakage on the NMOS devices of the output stages.

For example, a first output may be connected to the supply voltage, e.g., the VDD, for example, during packet dynamic off state, and a second output may be connected to the ground (GND). This situation may lead to leakage from supply ripples, for example, due to clock coupling to the output, e.g., affecting signal to Noise Ratio (SNR) in low transmitted power levels, for example, MOLO leakage effects.

Referring back to FIG. 1, in some demonstrative aspects, DPA 110 may be configured according to a dual-LS PA architecture utilizing a dual-LS 120, as described below.

In some demonstrative aspects, the dual-LS PA architecture may be configured to utilize two LSs, which may be implemented, for example, in the DPA cells, e.g., as described below.

In some demonstrative aspects, the dual-LS 120 may be configured to utilize the two LSs, for example, as single-ended drivers to an output stage of the DPA 110, e.g., as described below.

In some demonstrative aspects, the dual-LS PA architecture may be configured to provide a technical solution to support both outputs of the DPA 110, for example, to disconnect both output drivers of each cell from the supply voltage, for example, during the off state of the DPA 110, e.g., as described below.

In some demonstrative aspects, the dual-LS PA architecture may be configured to provide a technical solution to support removal of a supply Switch (SW) from a main supply rail in multi-device stacking structures, e.g., as described below.

For example, the direct supply voltage may trigger Gate-Induced-Drain-Leakage (GIDL), e.g., during the off-state of the cell, for example, especially in the output stages where large devices are presented.

In some demonstrative aspects, the dual-LS PA architecture may be configured to provide a technical solution to support disconnecting a supply leakage path in output stages of the DPA 110, for example, during the off state, e.g., as described below.

In some demonstrative aspects, the dual-LS PA architecture may be configured to provide a technical solution to support improved cost per product, for example, by avoiding a use of quality external DC SWs, which may be relatively expensive, and/or internal DC SWs, which may consume relatively large Silicone area.

In some demonstrative aspects, the dual-LS PA architecture may be configured to provide a technical solution to support improvement in a reduction of clock leakage coupled to a Supply rail, e.g., at package (pkg) or Board related paths, for example, by applying fully off cells outputs to a ground (GND) voltage, e.g., as described below.

For example, Modulated Local Oscillator (MOLO) leakage to the output may occur in low power transmitted powers, for example, due to connecting both outputs of statically off state cells to the GND voltage, e.g., during packet transmission.

In some demonstrative aspects, the dual-LS PA architecture may be configured to provide a technical solution to reduce the MOLO leakage, for example, by applying a Ground-Ground voltage for both outputs of un-used DPA cells, e.g., during a low power mode.

In some demonstrative aspects, the dual-LS PA architecture may be configured to provide a technical solution to support, e.g., ensure, smooth disconnecting of a high supply branch of the DPA 110, which may allow, for example, employing fast logic to toggle a low supply voltage and a high supply voltage e.g., efficiently, for example, during packet transmission.

In some demonstrative aspects, dual LS 120 may be configured to generate a differential LS output based on a differential input signal 159, e.g., as described below.

In some demonstrative aspects, the differential input signal 159 may include a negative input signal 151 and a positive input signal 157, e.g., as described below.

In some demonstrative aspects, negative input signal 151 may be opposite to the positive input signal 157. For example, when negative input signal 151 includes “0”, the positive input signal 157 may include “1”, and vice versa.

In some demonstrative aspects, the differential LS output may include a first LS output 172 and a second LS output 174, e.g., as described below.

In some demonstrative aspects, dual LS 120 may include a first LS 123 to provide a first single-ended LS output including the first LS output 172, for example, based on a first input signal 152, e.g., as described below.

In some demonstrative aspects, the first input signal 152 may be based, for example, on the negative input signal 151, e.g., as described below.

In some demonstrative aspects, dual LS 120 may include a second LS 125 to provide a second single-ended LS output including the second LS output 174, for example, based on a second input signal 154, e.g., as described below.

In some demonstrative aspects, the second input signal 154 may be based, for example, on the positive input signal 157, e.g., as described below.

In some demonstrative aspects, DPA 110 may include first PA circuitry 162, which may be configured to generate a first PA signal 163, for example, based on the first LS output 172, e.g., as described below.

In some demonstrative aspects, DPA 110 may include second PA circuitry 164, which may be configured to generate a second PA signal 165, for example, based on the second LS output 174, e.g., as described below.

In some demonstrative aspects, the first PA circuitry 162 and/or the second PA circuitry 164 may include, for example, one or more, e.g., some or all, components and/or elements, of the PA circuitry XX (FIG. 2D), for example, in case DPA 110 includes a single-mode PA.

In some demonstrative aspects, the first PA circuitry 162 and/or the second PA circuitry 164 may include, for example, one or more, e.g., some or all, components and/or elements, of the PA circuitry YY (FIG. 3D and FIG. 3E), for example, in case DPA 110 includes a multi-mode PA.

In some demonstrative aspects, the input of the level-shifters 123 and 125 may be cross connected, for example, to provide a technical solution to ensure the single-ended operation of the level shifters 123 and 125 may not affect the output differential operation, e.g., as described below.

In some demonstrative aspects, the first LS 123 may include first LS circuitry 141, which may be configured to provide the first single-ended LS output 172, for example, based on the first input signal 152, e.g., as described below.

In some demonstrative aspects, the first LS 123 may include second LS circuitry 142 to receive a second-LS-circuitry input signal 153, e.g., as described below.

In some demonstrative aspects, the second-LS-circuitry input signal 153 may be based, for example, on the positive input signal 157, e.g., as described below.

In some demonstrative aspects, the second-LS-circuitry input signal 153 may be, for example, opposite to the first input signal 152, e.g., as described below.

In some demonstrative aspects, the first LS 123 may include a cross-coupling connection 143 to cross-couple the first LS circuitry 141 of the first LS 123 and the second LS circuitry 142 of the first LS 123, e.g., as described below.

In some demonstrative aspects, the first LS circuitry 141 of the first LS 123 may include a plurality of transistors (not shown in FIG. 1) connected between a Drain Voltage (VDD) and a Supply Voltage (VSS), e.g., as described below.

In some demonstrative aspects, the first LS circuitry 141 of the first LS 123 may include an input node (not shown in FIG. 1) to input the first input signal 152, for example, to drive the plurality of transistors of the first LS circuitry 141 of the first LS 123 to generate the first single-ended LS output 172, e.g., as described below.

In some demonstrative aspects, the cross-coupling connection 143 of the first LS 123 may be configured to couple the second-LS-circuitry input signal 153 from the second LS circuitry 142 of the first LS 123 to a transistor node (not shown in FIG. 1) between first and second transistors in the plurality of transistors of the first LS circuitry 141 of the first LS 123, e.g., as described below.

In some demonstrative aspects, the second LS circuitry 142 of the first LS 123 may include a plurality of transistors (not shown in FIG. 1) connected between a VDD and a VSS, e.g., as described below.

In some demonstrative aspects, the second LS circuitry 142 of the first LS 123 may include an input node (not shown in FIG. 1) to input the second-LS-circuitry input signal 153 to drive the plurality of transistors of the second LS circuitry 142 of the first LS 123, e.g., as described below.

In some demonstrative aspects, the cross-coupling connection 143 of the first LS 123 may be configured to couple the first input signal 152 from the first LS circuitry 141 of the first LS 123 to a transistor node (not shown in FIG. 1) between first and second transistors in the plurality of transistors of the second LS circuitry 142 of the first LS 123, e.g., as described below.

In some demonstrative aspects, the second LS 125 may include first LS circuitry 161, which may be configured to provide the second single-ended LS output 174, for example, based on the second input signal 154, e.g., as described below.

In some demonstrative aspects, the second LS 125 may include second LS circuitry 162 to receive a second-LS-circuitry input signal 155, e.g., as described below.

In some demonstrative aspects, the second-LS-circuitry input signal 155 may be based, for example, on the negative input signal 151, e.g., as described below.

In some demonstrative aspects, the second-LS-circuitry input signal 155 may be, for example, opposite to the second input signal 154, e.g., as described below.

In some demonstrative aspects, the second LS 125 may include a cross-coupling connection 167 to cross-couple the first LS circuitry 161 of the second LS 125 and the second LS circuitry 162 of the second LS 125, e.g., as described below.

In some demonstrative aspects, the first LS circuitry 161 of the second LS 125 may include a plurality of transistors (not shown in FIG. 1) connected between a VDD and a VSS, e.g., as described below.

In some demonstrative aspects, the first LS circuitry 161 of the second LS 125 may include an input node (not shown in FIG. 1) to input the second input signal 154 to drive the plurality of transistors of the first LS circuitry 161 of the second LS 125, for example, to generate the second single-ended LS output 174, e.g., as described below.

In some demonstrative aspects, the cross-coupling connection 167 of the second LS 125 may be configured to couple the second-LS-circuitry input signal 155 from the second LS circuitry 162 of the second LS 125 to a transistor node (not shown in FIG. 1) between first and second transistors in the plurality of transistors of the first LS circuitry 161 of the second LS 125, e.g., as described below.

In some demonstrative aspects, the second LS circuitry 162 of the second LS 125 may include a plurality of transistors (not shown in FIG. 1) connected between a VDD and a VSS, e.g., as described below.

In some demonstrative aspects, the second LS circuitry 162 of the second LS 125 may include an input node (not shown in FIG. 1) to input the second-LS-circuitry input signal 155, for example, to drive the plurality of transistors of the second LS circuitry 162 of the second LS 125, e.g., as described below.

In some demonstrative aspects, the cross-coupling connection 167 of the second LS 125 may be configured to couple the second input signal 154 from the first LS circuitry 161 of the second LS 125 to a transistor node (not shown in FIG. 1) between first and second transistors in the plurality of transistors of the second LS circuitry 162 of the second LS 125, e.g., as described below.

In some demonstrative aspects, first PA circuitry 162 may include a first input node 111 connected to a first output node 113 of the first LS 123, e.g., as described below.

For example, first output node 113 of the first LS 123 may be connected to a first output node of the first LS circuitry 141 of the first LS 123.

In some demonstrative aspects, first PA circuitry 162 may include a second input node 112 connected to a second output node 114 of the first LS 123, e.g., as described below.

For example, second output node 114 of the first LS 123 may be connected to a second output node of the first LS circuitry 141 of the first LS 123.

In some demonstrative aspects, first PA circuitry 162 may include a PA output node 115 to provide the first PA signal 163, e.g., as described below.

In some demonstrative aspects, first PA circuitry 162 may include a first plurality of transistors (not shown in FIG. 1) connected in series between a first PA voltage and the PA output node 115, e.g., as described below.

In some demonstrative aspects, a gate of a transistor of the first plurality of transistors of the first PA circuitry 162 may be connected to the first input node 111, e.g., as described below.

In some demonstrative aspects, first PA circuitry 162 may include a second plurality of transistors (not shown in FIG. 1) connected in series between a second PA voltage and the PA output node 115, e.g., as described below.

In some demonstrative aspects, a gate of a transistor of the second plurality of transistors of the first PA circuitry 162 may be connected to the first input node 112, e.g., as described below.

In other aspects, the first PA circuitry 162 may include any other additional or alternative circuitry and/or components, and/or the first PA circuitry 162 may be configured according to any other suitable architecture.

In some demonstrative aspects, second PA circuitry 164 may include a first input node 131 connected to a first output node 133 of the second LS 125, e.g., as described below.

For example, first output node 133 of the second LS 125 may be connected to a first output node of the first LS circuitry 161 of the second LS 125.

In some demonstrative aspects, second PA circuitry 164 may include a second input node 132 connected to a second output node 134 of the second LS 125, e.g., as described below.

For example, second output node 134 of the second LS 125 may be connected to a second output node of the first LS circuitry 161 of the second LS 125.

In some demonstrative aspects, second PA circuitry 164 may include a PA output node 135 to provide the second PA signal 165, e.g., as described below.

In some demonstrative aspects, second PA circuitry 164 may include a first plurality of transistors (not shown in FIG. 1) connected in series between the first PA voltage and the PA output node 135, e.g., as described below.

In some demonstrative aspects, a gate of a transistor of the first plurality of transistors of the second PA circuitry 164 may be connected to the first input node 131, e.g., as described below.

In some demonstrative aspects, second PA circuitry 164 may include a second plurality of transistors (not shown in FIG. 1) connected in series between the second PA voltage and the PA output node 135, e.g., as described below.

In some demonstrative aspects, a gate of a transistor of the second plurality of transistors of the second PA circuitry 164 may be connected to the first input node 132, e.g., as described below.

In some demonstrative aspects, the first PA voltage, e.g., of the first PA circuitry 164 and/or the second PA circuitry 164, may be, for example, at least two times the second PA voltage, e.g., as described below.

In some demonstrative aspects, the first PA voltage, e.g., of the first PA circuitry 164 and/or the second PA circuitry 164, may be, for example, at least three times the second PA voltage, e.g., as described below.

In other aspects, the first PA voltage and/or the second PA voltage of the first PA circuitry 164 and/or the second PA circuitry 164 may include any other voltages.

In other aspects, the second PA circuitry 164 may include any other additional or alternative circuitry and/or components, and/or the second PA circuitry 164 may be configured according to any other suitable architecture.

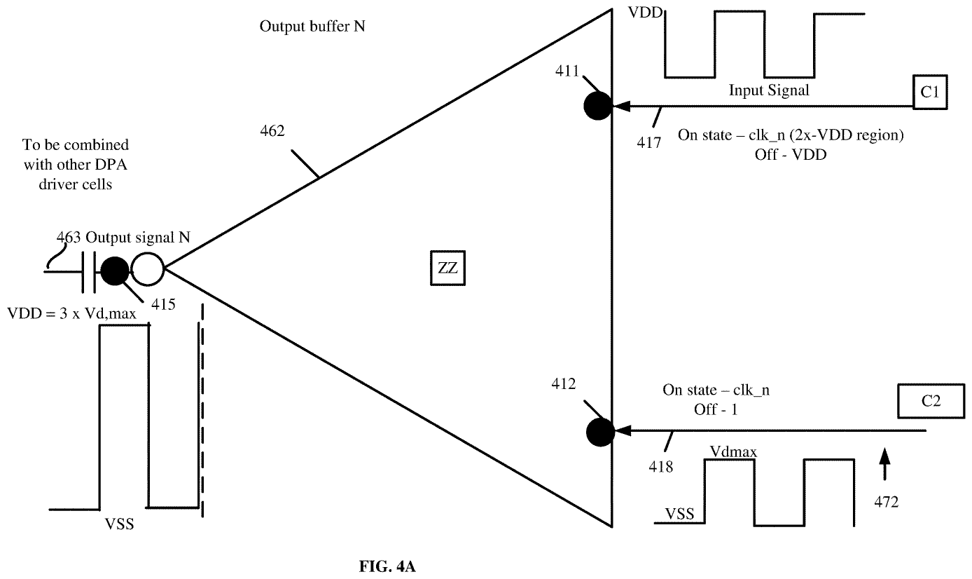

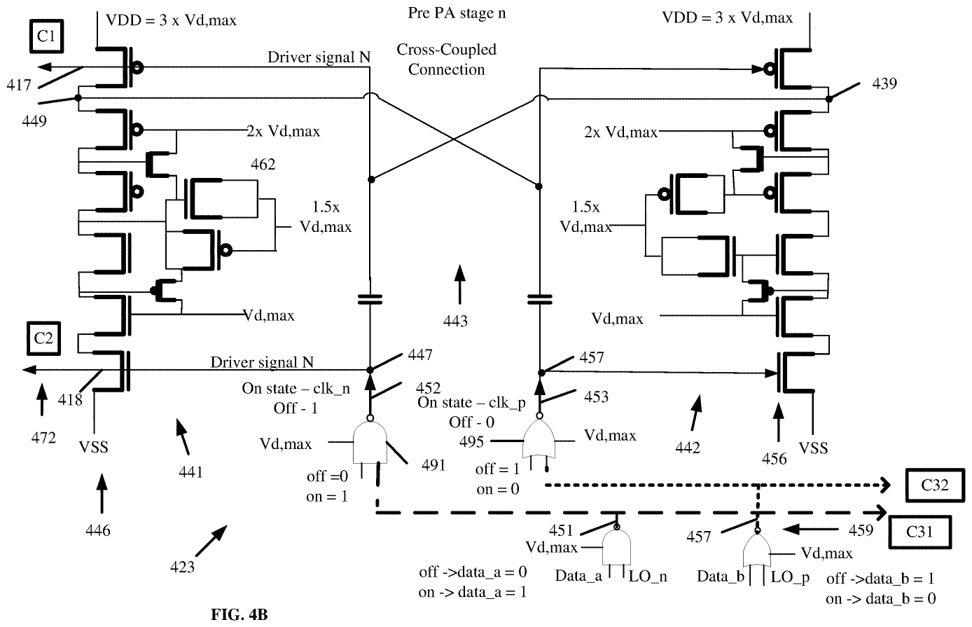

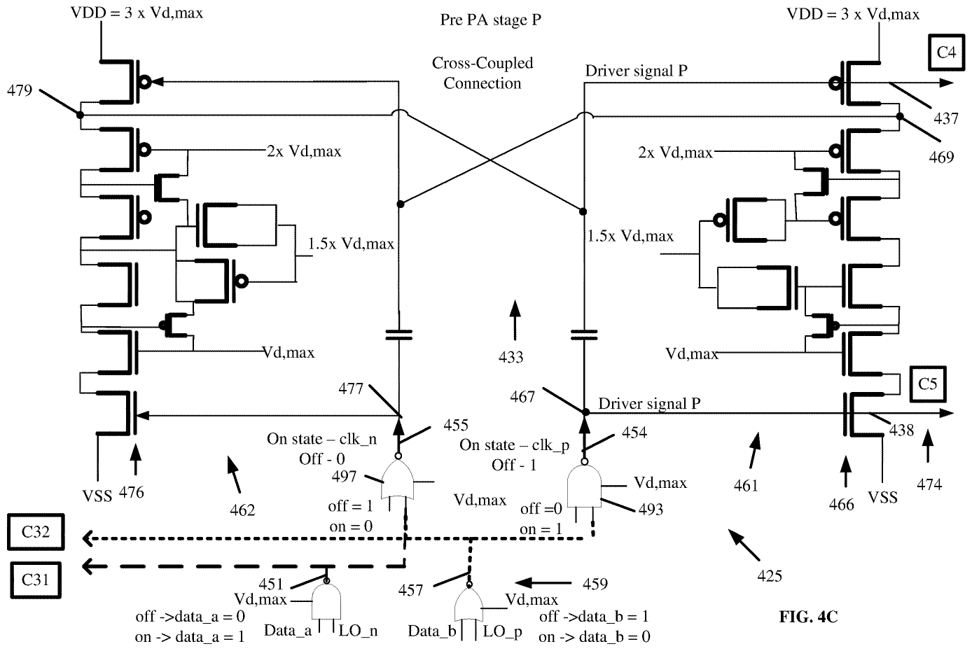

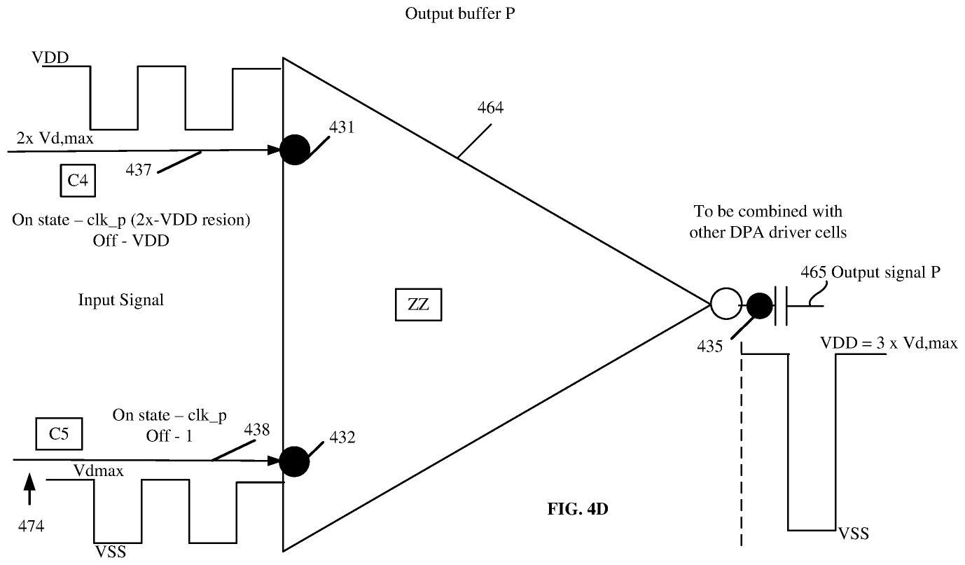

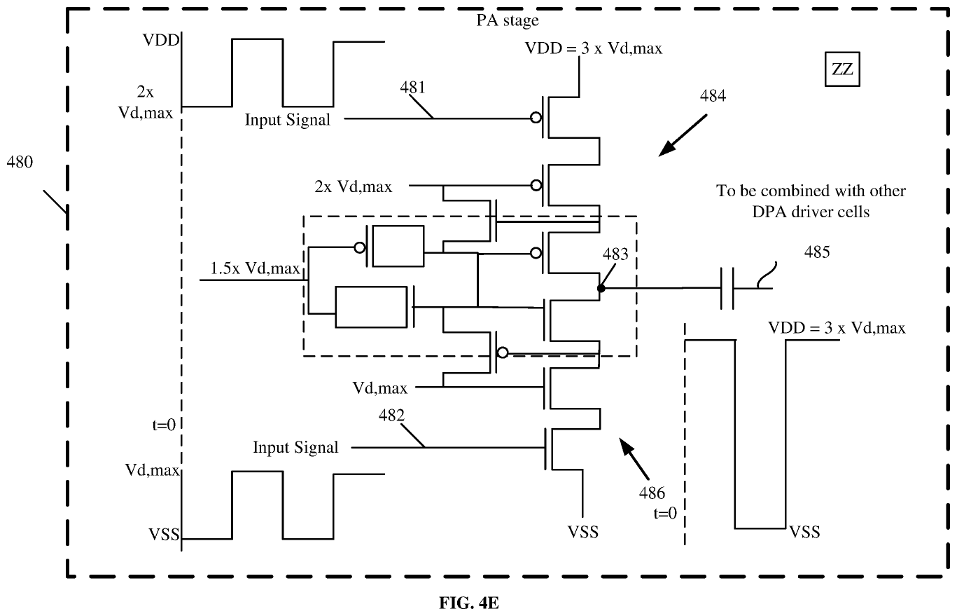

In some demonstrative aspects, the DPA 110 may include a single-mode DPA, e.g., as described below with reference to FIG. 4.

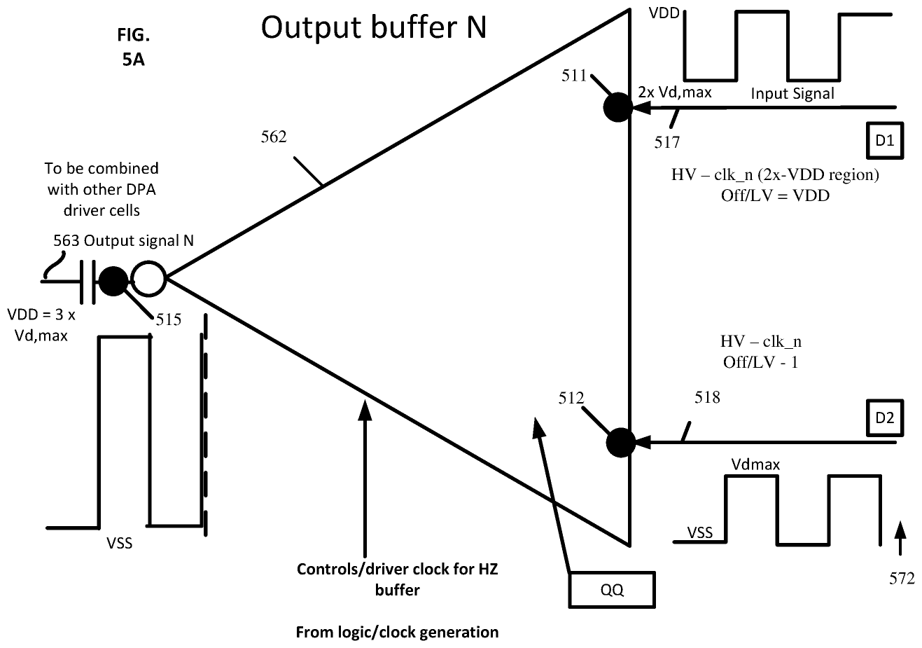

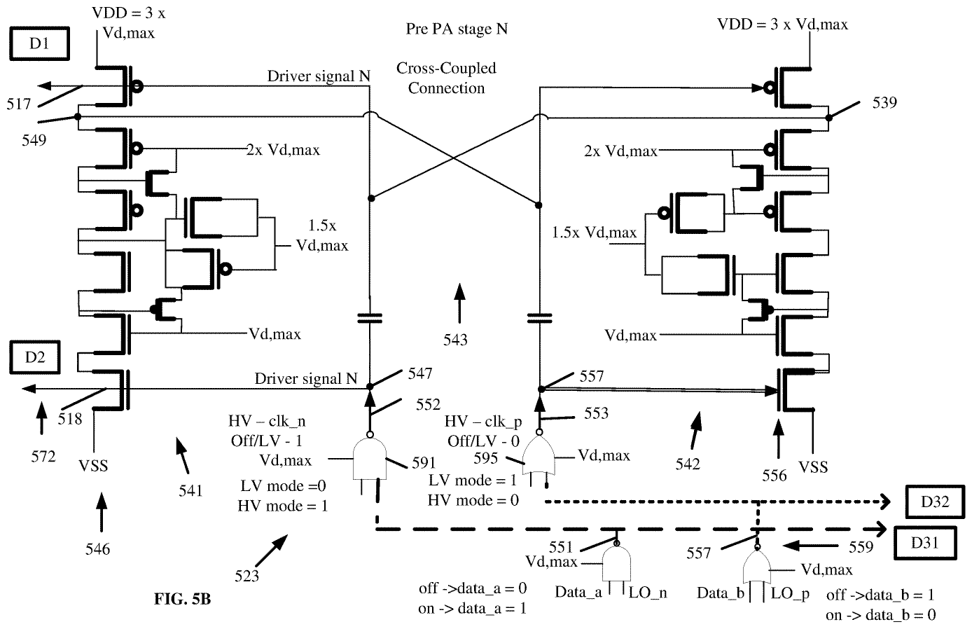

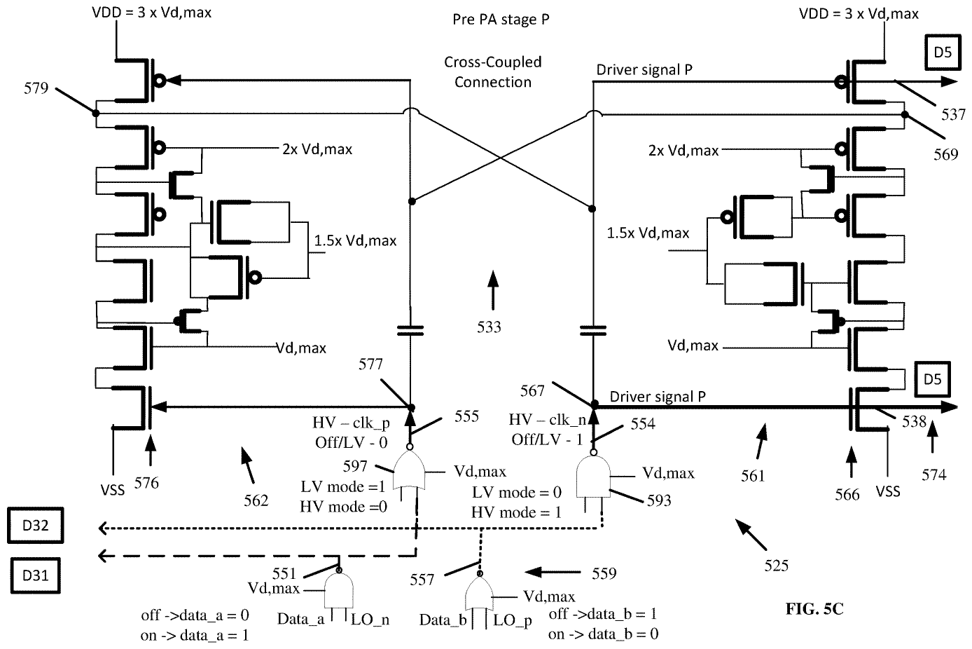

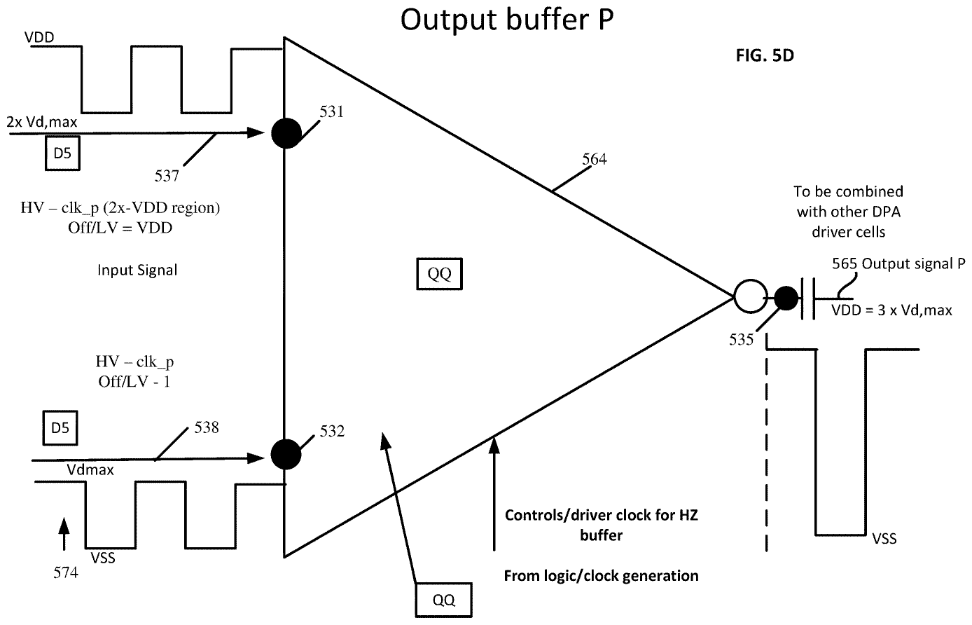

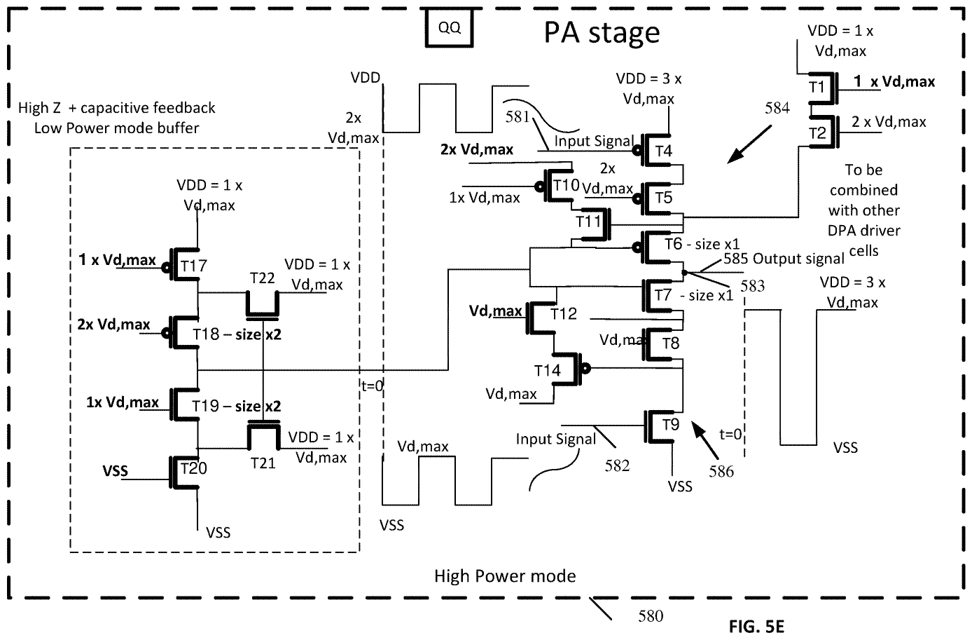

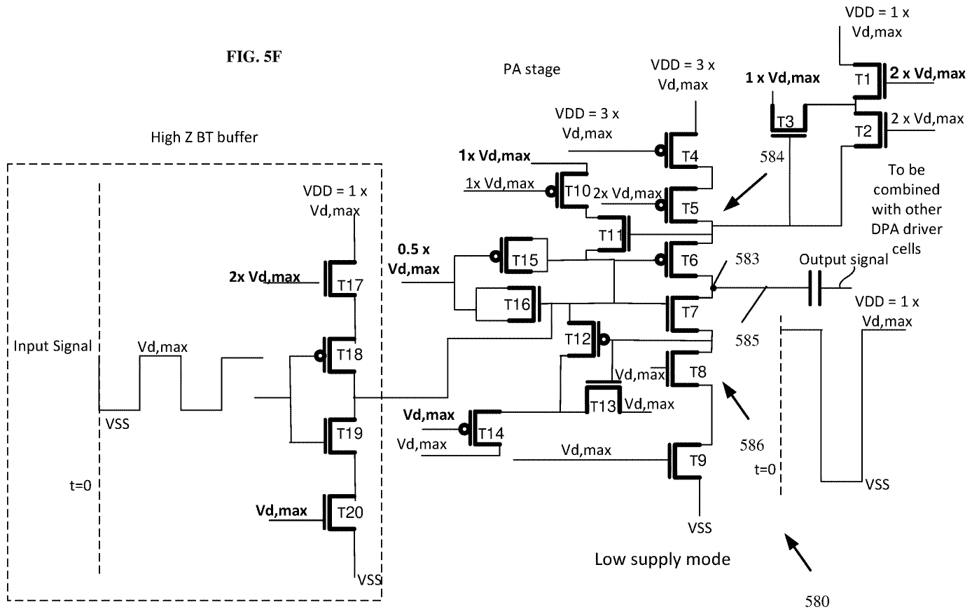

In some demonstrative aspects, the DPA 110 may include a multi-mode DPA, which may be switchable between a plurality of power modes, for example, to generate a DPA output signal based on the differential input signal 159 in a first voltage domain, e.g., as described below with reference to FIG. 5.

In some demonstrative aspects, the multi-mode DPA may be configured to provide the DPA output signal in the first voltage domain at a first power mode, e.g., as described below with reference to FIG. 5.

In some demonstrative aspects, the multi-mode DPA may be configured to provide the DPA output signal in a second voltage domain at a second power mode, e.g., as described below with reference to FIG. 5.

In some demonstrative aspects, the differential input signal 159 may be in a first voltage domain, e.g., as described below.

In some demonstrative aspects, the first PA signal 163 and the second PA signal 165 may be, for example, in a second voltage domain, e.g., as described below.

In some demonstrative aspects, a maximal voltage of the second voltage domain may be, for example, at least two times a maximal voltage of the first voltage domain, e.g., as described below.

In some demonstrative aspects, the maximal voltage of the second voltage domain may be, for example, at least three times the maximal voltage of the first voltage domain, e.g., as described below.

In other aspects, the maximal voltage of the second voltage domain and/or the maximal voltage of the first voltage domain may include any other voltages.

In some demonstrative aspects, the DPA 110 may include a controller 150, which may be configured to control a state of the DPA 110, e.g., as described below.

In some demonstrative aspects, controller 150 may be configured to control a setting of the first input signal 152 and/or a setting of the second input signal 154, for example, according to the state of the DPA 110, e.g., as described below.

In some demonstrative aspects, DPA 110 may include logic circuitry 189, which may be configured to generate one or more of the input signals 152, 153, 154 and/or 155, for example, based on the negative input signal 151 and/or the positive input signal 157, e.g., as described below.

In some demonstrative aspects, the logic circuitry 189 may include one or more logic circuits, e.g., NAND and/or NOR circuits and/or any other logic circuits to be applied to the negative input signal 151 and/or the positive input signal 157, e.g., as described below.

In some demonstrative aspects, controller 150 may be configured to control the logic circuitry 189, for example, according to the state of the DPA 110, e.g., as described below.

In some demonstrative aspects, dual LS 120 may be configured to generate the first LS output 172 to be equal to the second LS output 174, for example, based on a particular setting of the first input signal 152 and the second input signal 154, e.g., as described below.

In some demonstrative aspects, controller 150 may be configured to control the particular setting of the first input signal 152 and the second input signal 154, for example, by controlling the logic circuitry 189, e.g., as described below.

In some demonstrative aspects, the first LS output 172 may include a first LS output signal 117, e.g., provided at output node 113, and a second LS output signal 118, e.g., provided at output node 114, as described below.

In some demonstrative aspects, the second LS output 174 may include a third LS output signal 137, e.g., provided at output node 133, and a fourth LS output signal 138, e.g., provided at output node 134, e.g., as described below.

In some demonstrative aspects, the dual LS 120 may be configured to generate the first LS output signal 117 to be equal to the third LS output signal 137, and the second LS output signal 118 to be equal to the fourth LS output signal 138, for example, based on the particular setting of the first input signal 152 and the second input signal 154, e.g., as described below.

In some demonstrative aspects, the dual LS 120 may be configured to generate the first LS output signal 117 and the third LS output signal 137 including the VDD, for example, based on the particular setting of the first input signal 152 and the second input signal 154, e.g., as described below.

In some demonstrative aspects, the dual LS 120 may be configured to generate the second LS output signal 118 and the fourth LS output signal 138 including a logic “1” voltage, for example, based on the particular setting of the first input signal 152 and the second input signal 154, e.g., as described below.

In some demonstrative aspects, the VDD may be at least two times the logic “1” voltage, e.g., as described below.

In some demonstrative aspects, the VDD may be at least three times the logic “1” voltage, e.g., as described below.

In other aspects, the VDD and/or the logic “1” voltage may include any other voltages.

In some demonstrative aspects, the particular setting of the first input signal 152 and the second input signal 154 may include, for example, a setting of the first input signal 152 equal to a setting of the second input signal 154, e.g., as described below.

In some demonstrative aspects, the particular setting of the first input signal 152 and the second input signal 154 may include a setting of the first input signal 152 and the second input signal 154 to the logic “1” voltage, e.g., as described below.

In other aspects, the particular setting of the first input signal 152 and the second input signal 154 may include any other suitable setting of the first input signal 152 and the second input signal 154.

In some demonstrative aspects, the dual LS 120 may be configured to generate the first LS output 172 to be different from the second LS output 174, for example, based on an other setting of the first input signal 152 and the second input signal 154, e.g., as described below.

In some demonstrative aspects, controller 150 may be configured to control the other setting of the first input signal 152 and the second input signal 154, for example, by controlling the logic circuitry 189, e.g., as described below.

In some demonstrative aspects, the other setting of the first input signal 152 and the second input signal 154 may include a setting of the first input signal 152 different from a setting of the second input signal 154, e.g., as described below.

In some demonstrative aspects, the other setting of the first input signal 152 and the second input signal 154 may include a setting of the first input signal 152 to include the negative input signal 151, e.g., as described below.

In some demonstrative aspects, the other setting of the first input signal 152 and the second input signal 154 may include a setting of the second input signal 154 to include the positive input signal 157, e.g., as described below.

In other aspects, the other setting of the first input signal 152 and the second input signal 154 may include any other suitable setting of the first input signal 152 and the second input signal 154.

In some demonstrative aspects, the particular setting of the first input signal 152 and the second input signal 154 may correspond to a first state of the DPA 110, e.g., as described below.

In some demonstrative aspects, the other setting of the first input signal 152 and the second input signal 154 may correspond to a second state of the DPA 110, e.g., as described below.

In some demonstrative aspects, the particular setting of the first input signal 152 and the second input signal 154 may correspond to an off-state of the DPA 110, e.g., as described below.

In some demonstrative aspects, the other setting of the first input signal 152 and the second input signal 154 may correspond to an on-state of the DPA 110, e.g., as described below.

In some demonstrative aspects, the particular setting of the first input signal 152 and the second input signal 154 may correspond to the off-state of the DPA 110, and the other setting of the first input signal 152 and the second input signal 154 may correspond to the on-state of the DPA 110, for example, in case the DPA 110 includes a single mode DPA, e.g., as described below.

In some demonstrative aspects, the particular setting of the first input signal 152 and the second input signal 154 may correspond to a first power mode of the DPA 110, e.g., as described below.

In some demonstrative aspects, the other setting of the first input signal 152 and the second input signal 154 may correspond to a second power mode of the DPA 110, e.g., as described below.

In some demonstrative aspects, the particular setting of the first input signal 152 and the second input signal 154 may correspond to the first power mode of the DPA 110, and the other setting of the first input signal 152 and the second input signal 154 may correspond to the second power mode of the DPA 110, for example, in case the DPA 110 includes a multi-mode DPA, e.g., as described below.

In one example, the particular setting of the first input signal 152 and the second input signal 154 may correspond to a low-power mode of the DPA 110, and the other setting of the first input signal 152 and the second input signal 154 may correspond to a high-power mode of the DPA 110, for example, in case the DPA 110 includes the multi-mode DPA, e.g., as described below.

In other aspects, the particular setting of the first input signal 152 and the second input signal 154, and/or the other setting of the first input signal 152 and the second input signal 154 may correspond to any other additional or alternative states and/or power modes of the DPA 110.

In some demonstrative aspects, leakage simulations for the single-mode cell DPA 110 based on the dual LS 120 may show a reduction of the leakage in the output stage of DPA 110 to about 2 nano Ampere (nA). This reduced leakage may be compared, for example, to a leakage of about 100 nA, e.g., when a single LS is used.

In some demonstrative aspects, for example, by applying both outputs to GND, we may apply to all of the drains or sources of the NMOS devices in DPA 110 in the stacking structure to ground. This way the Bulk-Source and Bulk-Drain of the NMOS devices may have substantially Zero potential. Accordingly, substantially no current will flow to the bulk in this mode, e.g., the off-mode or low power-mode.

Reference is made to FIGS. 4A, 4B, 4C, 4D and 4E, which schematically illustrate a single-mode DPA with a dual LS, in accordance with some demonstrative aspects.

In some demonstrative aspects, DPA 110 (FIG. 1) may include one or more elements and/or components of the single-mode DPA with the dual LS of FIGS. 4A-4E.

In some demonstrative aspects, DPA 110 (FIG. 1) may include first PA circuitry 462 (FIG. 4A) and second PA circuitry 464 (FIG. 4D).

For example, PA circuitry 162 (FIG. 1) may include one or more elements and/or components of the PA circuitry 432 (FIG. 4A), e.g., as shown in FIG. 4E.

For example, PA circuitry 164 (FIG. 1) may include one or more elements and/or components of the PA circuitry 464 (FIG. 4D), e.g., as shown in FIG. 4E.

In some demonstrative aspects, the dual LS may include a first LS 423 (FIG. 4B) and a second LS 425 (FIG. 4C).

For example, LS 123 (FIG. 1) may include one or more elements and/or components of the LS 423 of FIG. 4C.

For example, LS 125 (FIG. 1) may include one or more elements and/or components of the LS 425 of FIG. 4D.

In some demonstrative aspects, as shown in FIG. 4B and FIG. 4C, the dual LS may be configured to generate a differential LS output, e.g., including a first LS output 472 and a second LS output 474, for example, based on a differential input signal 459.

In some demonstrative aspects, as shown in FIG. 4B and FIG. 4C, the differential input signal 459 may include a negative input signal 451 and a positive input signal 457.

In some demonstrative aspects, negative input signal 451 may be opposite to the positive input signal 457. For example, when negative input signal 451 includes “0”, the positive input signal 457 may include “1”, and vice versa.

In some demonstrative aspects, as shown in FIG. 4B, first LS 423 may be configured to provide a first single-ended LS output including the first LS output 472, for example, based on a first input signal 452.

In some demonstrative aspects, as shown in FIG. 4B, the first input signal 452 may be based, for example, on the negative input signal 451.

In some demonstrative aspects, as shown in FIG. 4C, second LS 425 may be configured to provide a second single-ended LS output including the second LS output 474, for example, based on a second input signal 454.

In some demonstrative aspects, as shown in FIG. 4C, the second input signal 454 may be based, for example, on the positive input signal 457.

In some demonstrative aspects, as shown in FIG. 4B and FIG. 4C, the single-mode DPA with the dual LS may include logic circuitry, which may be configured to generate the first input signal 452 and the second input signal 454, for example, based on the negative input signal 451 and the positive input signal 457.

For example, as shown in FIG. 4B, the single-mode DPA with the dual LS may include a first logical NAND gate 491, which may be configured to generate the first input signal 452 based on the negative input signal 451 and a control signal, e.g., having a first value (off) or a second value (on).

For example, as shown in FIG. 4C, the single-mode DPA with the dual LS may include a second logical NAND gate 493, which may be configured to generate the second input signal 454 based on the positive input signal 457 and the control signal.

For example, the control signal may be provided by a controller, e.g., controller 150 (FIG. 1), for example, based on a state and/or mode of operation of the DPA, e.g., as described above.

In some demonstrative aspects, as shown in FIG. 4A, first PA circuitry 462 may be configured to generate a first PA signal 463, for example, based on the first LS output 472.

In some demonstrative aspects, as shown in FIG. 4D, PA circuitry 464 may be configured to generate a second PA signal 465, for example, based on the second LS output 474.

In some demonstrative aspects, the first PA circuitry 462 and/or the second PA circuitry 464 may include, for example, one or more, e.g., some or all, components and/or elements, of a PA circuitry denoted “ZZ”, e.g., as shown in FIG. 4E.

In some demonstrative aspects, as shown in FIG. 4B and FIG. 4C, the inputs of the level-shifters 423 and 425 may be cross connected, for example, to provide a technical solution to ensure that the single-ended operation of the level shifters 423 and 425 may not substantially affect the output differential operation.

In some demonstrative aspects, as shown in FIG. 4B, the first LS 423 may include first LS circuitry 441, which may be configured to provide the first single-ended LS output 472, for example, based on the first input signal 452.

In some demonstrative aspects, as shown in FIG. 4B, the first LS 423 may include second LS circuitry 442 to receive a second-LS-circuitry input signal 453.

In some demonstrative aspects, as shown in FIG. 4B, the second-LS-circuitry input signal 453 may be based, for example, on the positive input signal 457.

In some demonstrative aspects, as shown in FIG. 4B, the second-LS-circuitry input signal 453 may be, for example, opposite to the first input signal 452.

In some demonstrative aspects, as shown in FIG. 4B, the single-mode DPA with the dual LS may include a first logical NOR gate 495, which may be configured to generate the second-LS-circuitry input signal 453 based on the positive input signal 457 and the control signal, e.g., from controller 150 (FIG. 1).

In some demonstrative aspects, as shown in FIG. 4B, the first LS 423 may include a cross-coupling connection 443 to cross-couple the first LS circuitry 441 of the first LS 423 and the second LS circuitry 442 of the first LS 423.

In some demonstrative aspects, as shown in FIG. 4B, the first LS circuitry 441 of the first LS 423 may include a plurality of transistors 446 connected, e.g., in series, between a VDD and a VSS.

In some demonstrative aspects, as shown in FIG. 4B, the first LS circuitry 441 of the first LS 423 may include an input node 447 to input the first input signal 452, for example, to drive the plurality of transistors 446, for example, to generate the first single-ended LS output 472.

In some demonstrative aspects, as shown in FIG. 4B, the cross-coupling connection 443 of the first LS 423 may be configured to couple the second-LS-circuitry input signal 453 from the second LS circuitry 442 of the first LS 423 to a transistor node 449, which may be between first and second transistors in the plurality of transistors 446.

In some demonstrative aspects, as shown in FIG. 4B, the second LS circuitry 442 of the first LS 423 may include a plurality of transistors 456 connected, e.g., in series, between a VDD and a VSS.

In some demonstrative aspects, as shown in FIG. 4B, the second LS circuitry 442 of the first LS 423 may include an input node 457 to input the second-LS-circuitry input signal 453 to drive the plurality of transistors 456.

In some demonstrative aspects, as shown in FIG. 4B, the cross-coupling connection 443 of the first LS 423 may be configured to couple the first input signal 452 from the first LS circuitry 441 of the first LS 423 to a transistor node 439 between first and second transistors in the plurality of transistors 456.

In some demonstrative aspects, as shown in FIG. 4C, the second LS 425 may include first LS circuitry 461 to provide the second single-ended LS output 474, for example, based on the second input signal 454.

In some demonstrative aspects, as shown in FIG. 4C, the second LS 425 may include second LS circuitry 462 to receive a second-LS-circuitry input signal 455.

In some demonstrative aspects, as shown in FIG. 4C, the second-LS-circuitry input signal 455 may be based, for example, on the negative input signal 451.

In some demonstrative aspects, as shown in FIG. 4C, the second-LS-circuitry input signal 455 may be, for example, opposite to the second input signal 454.

In some demonstrative aspects, as shown in FIG. 4C, the single-mode DPA with the dual LS may include a second logical NOR gate 497, which may be configured to generate the second-LS-circuitry input signal 455 based on the negative input signal 451 and the control signal, e.g., from controller 150 (FIG. 1).

In some demonstrative aspects, as shown in FIG. 4C, the second LS 425 may include a cross-coupling connection 433 to cross-couple the first LS circuitry 461 of the second LS 425 and the second LS circuitry 462 of the second LS 425.

In some demonstrative aspects, as shown in FIG. 4C, the first LS circuitry 461 of the second LS 425 may include a plurality of transistors 466 connected, e.g., in series, between a VDD and a VSS.

In some demonstrative aspects, as shown in FIG. 4C, the first LS circuitry 461 of the second LS 425 may include an input node 467 to input the second input signal 454 to drive the plurality of transistors 466, for example, to generate the second single-ended LS output 474.

In some demonstrative aspects, as shown in FIG. 4C, the cross-coupling connection 433 of the second LS 425 may be configured to couple the second-LS-circuitry input signal 455 from the second LS circuitry 462 of the second LS 425 to a transistor node 469 between first and second transistors in the plurality of transistors 466.

In some demonstrative aspects, as shown in FIG. 4C, the second LS circuitry 462 of the second LS 425 may include a plurality of transistors 476 connected, e.g., in series, between a VDD and a VSS.

In some demonstrative aspects, as shown in FIG. 4C, the second LS circuitry 462 of the second LS 425 may include an input node 477 to input the second-LS-circuitry input signal 455, for example, to drive the plurality of transistors 476.

In some demonstrative aspects, as shown in FIG. 4C, the cross-coupling connection 433 of the second LS 425 may be configured to couple the second input signal 454 from the first LS circuitry 461 of the second LS 425 to a transistor node 479 between first and second transistors in the plurality of transistors 476.

In some demonstrative aspects, as shown in FIG. 4B, the first LS output 472 may include a first LS output signal 417 and a second LS output signal 418.

In some demonstrative aspects, as shown in FIG. 4C, the second LS output 474 may include a third LS output signal 437 and a fourth LS output signal 438.

In some demonstrative aspects, as shown in FIG. 4A and FIG. 4D, the dual LS may be configured to generate the first LS output signal 417 to be equal to the third LS output signal 437, and the second LS output signal 418 to be equal to the fourth LS output signal 438, for example, based on an off-state setting of the first input signal 452 and the second input signal 454.

In some demonstrative aspects, the off-state settings of the first input signal 452 and the second input signal 454 may correspond to an off-state of the single mode DPA.

In some demonstrative aspects, as shown in FIG. 4A and FIG. 4D, the dual LS 420 may be configured to generate the first LS output signal 417 and the third LS output signal 437 to include the VDD, and the second LS output signal 418 and the fourth LS output signal 438 to include the logic “1” voltage, for example, based on the off-state setting of the first input signal 452 and the second input signal 454.

In some demonstrative aspects, as shown in FIG. 4B and FIG. 4C, the off-state setting of the first input signal 452 and the second input signal 454 may include, for example, a setting of the first input signal 452 to be equal to a setting of the second input signal 454.

In some demonstrative aspects, as shown in FIG. 4B and FIG. 4C, the off-state setting of the first input signal 452 and the second input signal 454 may include a setting of the first input signal 452 and the second input signal 454 to the logic “1” voltage.

In some demonstrative aspects, as shown in FIG. 4A and FIG. 4D, the dual LS 420 may be configured to generate the first LS output 472 to be different from the second LS output 474, for example, based on an on-state setting of the first input signal 452 and the second input signal 454.

In some demonstrative aspects, the on-state setting of the first input signal 452 and the second input signal 454 may correspond to an on-state of the single mode DPA.

In some demonstrative aspects, as shown in FIG. 4A and FIG. 4D, the first LS output 472 may include a clk_n signal, and the second LS output 474 may include a clk_p signal, for example, at the on-state of the single mode DPA.

In some demonstrative aspects, as shown in FIG. 4B and FIG. 4C, the on-state setting of the first input signal 452 and the second input signal 454 may include a setting of the first input signal 452 to be different from a setting of the second input signal 454.

In some demonstrative aspects, as shown in FIG. 4B and FIG. 4C, the on-state setting of the first input signal 452 and the second input signal 454 may include a setting of the first input signal 452 to include the negative input signal 451, e.g., including an LO_n signal, and a setting of the second input signal 454 to include the positive input signal 457, e.g., including an LO_p signal.

In some demonstrative aspects, as shown in FIG. 4A, first PA circuitry 462 may include a first input node 411, which may be connected to a first output node, e.g., output node 113 (FIG. 1), of the first LS 423, e.g., to receive the first LS output signal 417.

In some demonstrative aspects, as shown in FIG. 4A, first PA circuitry 462 may include a second input node 412 connected to a second output node, e.g., output node 114 (FIG. 1), of the first LS 423 e.g., to receive the second LS output signal 418.

In some demonstrative aspects, as shown in FIG. 4A, first PA circuitry 462 may include a PA output node 415 to provide the first PA signal 463.

In some demonstrative aspects, as shown in FIG. 4D, second PA circuitry 464 may include a first input node 431 connected to a first output node of the second LS 425, e.g., output node 133 (FIG. 1), e.g., to receive the third LS output signal 437.

In some demonstrative aspects, as shown in FIG. 4D, second PA circuitry 464 may include a second input node 432 connected to a second output node, e.g., output node 134 (FIG. 1), of the second LS 425, e.g., to receive the fourth LS output signal 438.

In some demonstrative aspects, as shown in FIG. 4D, second PA circuitry 464 may include a PA output node 435 to provide the second PA signal 465.

In some demonstrative aspects, the first PA circuitry 462 and/or the second PA circuitry 464 may include, for example, one or more, e.g., some or all, components and/or elements, of PA circuitry 480 (FIG. 4E).

In some demonstrative aspects, PA circuitry 480 may be connected to an LS, e.g., LS 423 (FIG. 4B) or LS 425 (FIG. 4C).

In some demonstrative aspects, as shown in FIG. 4E, PA circuitry 480 may include a first input node 481, which may be connected to a first output node of the LS. For example, first input node 481 may be connected to output node 113 (FIG. 1) of LS 423 (FIG. 4B), e.g., in case PA circuitry 480 is implemented as part of PA circuitry 462 (FIG. 4A). For example, first input node 481 may be connected to output node 133 (FIG. 1) of LS 425 (FIG. 4C), e.g., in case PA circuitry 480 is implemented as part of PA circuitry 464 (FIG. 4D).

In some demonstrative aspects, as shown in FIG. 4E, PA circuitry 480 may include a second input node 482, which may be connected to a second output node of the LS. For example, second input node 482 may be connected to output node 114 (FIG. 1) of LS 423 (FIG. 4B), e.g., in case PA circuitry 480 is implemented as part of PA circuitry 462 (FIG. 4A). For example, second input node 482 may be connected to output node 134 (FIG. 1) of LS 425 (FIG. 4C), e.g., in case PA circuitry 480 is implemented as part of PA circuitry 464 (FIG. 4D).

In some demonstrative aspects, as shown in FIG. 4E, PA circuitry 480 may include a PA output node 483 to provide a PA signal 485. For example, PA output node 415 (FIG. 4A) may include PA output node 483, e.g., in case PA circuitry 480 is implemented as part of PA circuitry 462 (FIG. 4A). For example, PA output node 435 (FIG. 4D) may include PA output node 483, e.g., in case PA circuitry 480 is implemented as part of PA circuitry 464 (FIG. 4D).

In some demonstrative aspects, as shown in FIG. 4E, PA circuitry 480 may include a first plurality of transistors 484 connected in series between a VDD and the PA output node 483.

In some demonstrative aspects, as shown in FIG. 4E, a gate of a transistor of the first plurality of transistors 484 may be connected to the first input node 481.

In some demonstrative aspects, as shown in FIG. 4E, PA circuitry 480 may include a second plurality of transistors 486 connected in series between a VSS and the PA output node 483.

In some demonstrative aspects, as shown in FIG. 4E, a gate of a transistor of the second plurality of transistors 486 may be connected to the second input node 482.

In some demonstrative aspects, as shown in FIG. 4E, the VDD may be equal to 3xVd,max, which may be at least three times the VSS.

In some demonstrative aspects, as shown in FIG. 4B and FIG. 4C, the differential input signal 459 may be in a voltage domain of a VDD region.

In some demonstrative aspects, as shown in FIG. 4A and FIG. 4D, the first PA signal 463 and the second PA signal 465 may be, for example, in a second voltage domain of a 3xVDD region.

Reference is made to FIGS. 5A, 5B, 5C, 5D, 5E, and 5F, which schematically illustrate a dual-mode DPA with a dual LS, in accordance with some demonstrative aspects.

In some demonstrative aspects, DPA 110 (FIG. 1) may include one or more elements and/or components of the dual-mode DPA with the dual LS of FIGS. 5A-5F.

In some demonstrative aspects, the dual-mode DPA may include a first PA circuitry 562 and a second PA circuitry 564.

For example, PA circuitry 162 (FIG. 1) may include one or more elements and/or components of the PA circuitry 562 of FIG. 5A, e.g., as shown in FIGS. 5E and 5F.

For example, PA circuitry 164 (FIG. 1) may include one or more elements and./or components of the PA circuitry 564 of FIG. 5D, e.g., as shown in FIGS. 5E and 5F.

For example, 5E illustrates PA output stage circuitry 580 operable at a high-power mode of the dual-mode DPA.

For example, FIG. 5F illustrates the PA output stage circuitry 580 operable at a low-power mode of the dual-mode DPA.

In some demonstrative aspects, the dual LS may include a first LS 523 (FIG. 5B) and a second LS 525 (FIG. 5C).

For example, LS 123 (FIG. 1) may include one or more elements and/or components of the LS of FIG. 5C.

For example, LS 125 (FIG. 1) may include one or more elements and/or components of the LS of FIG. 5D.

In some demonstrative aspects, as shown in FIG. 5B and FIG. 5C, the dual LS may be configured to generate a differential LS output, e.g., including a first LS output 572 and a second LS output 574, for example, based on a differential input signal 559.

In some demonstrative aspects, as shown in FIG. 5B and FIG. 5C, the differential input signal 559 may include a negative input signal 551 and a positive input signal 557.

In some demonstrative aspects, negative input signal 551 may be opposite to the positive input signal 557. For example, when negative input signal 551 includes “0”, the positive input signal 557 may include “1”, and vice versa.

In some demonstrative aspects, as shown in FIG. 5B, first LS 523 may be configured to provide a first single-ended LS output including the first LS output 572, for example, based on a first input signal 552.

In some demonstrative aspects, as shown in FIG. 5B, the first input signal 552 may be based, for example, on the negative input signal 551.

In some demonstrative aspects, as shown in FIG. 5C, second LS 525 may be configured to provide a second single-ended LS output including the second LS output 574, for example, based on a second input signal 554.

In some demonstrative aspects, as shown in FIG. 5C, the second input signal 554 may be based, for example, on the positive input signal 557.

In some demonstrative aspects, as shown in FIG. 5B and FIG. 5C, the single-mode DPA with the dual LS may include logic circuitry, which may be configured to generate the first input signal 552 and the second input signal 554, for example, based on the negative input signal 551 and the positive input signal 557.

For example, as shown in FIG. 5B, the single-mode DPA with the dual LS may include a first logical NAND gate 591, which may be configured to generate the first input signal 552 based on the negative input signal 551 and a control signal, e.g., having a first value (off) or a second value (on).

For example, as shown in FIG. 5C, the single-mode DPA with the dual LS may include a second logical NAND gate 593, which may be configured to generate the second input signal 554 based on the positive input signal 557 and the control signal.

For example, the control signal may be provided by a controller, e.g., controller 150 (FIG. 1), for example, based on a state and/or mode of operation of the DPA, e.g., as described above.

In some demonstrative aspects, as shown in FIG. 5A, first PA circuitry 562 may be configured to generate a first PA signal 563, for example, based on the first LS output 572.

In some demonstrative aspects, as shown in FIG. 5D, PA circuitry 564 may be configured to generate a second PA signal 565, for example, based on the second LS output 574.

In some demonstrative aspects, the first PA circuitry 562 and/or the second PA circuitry 564 may include, for example, one or more, e.g., some or all, components and/or elements, of a PA circuitry, denoted “QQ”, e.g., as shown in FIG. 5E and FIG. 5F.

In some demonstrative aspects, as shown in FIG. 5B and FIG. 5C, the input of the level-shifters 523 and 525 may be cross connected, for example, to provide a technical solution to ensure that the single-ended operation of the level shifters 523 and 525 may not substantially affect the output differential operation.

In some demonstrative aspects, as shown in FIG. 5B, the first LS 523 may include first LS circuitry 541, which may be configured to provide the first single-ended LS output 572, for example, based on the first input signal 552.

In some demonstrative aspects, as shown in FIG. 5B, the first LS 523 may include second LS circuitry 542 to receive a second-LS-circuitry input signal 553.

In some demonstrative aspects, as shown in FIG. 5B, the second-LS-circuitry input signal 553 may be based, for example, on the positive input signal 557.

In some demonstrative aspects, as shown in FIG. 5B, the second-LS-circuitry input signal 553 may be, for example, opposite to the first input signal 552.

In some demonstrative aspects, as shown in FIG. 5B, the single-mode DPA with the dual LS may include a first logical NOR gate 595, which may be configured to generate the second-LS-circuitry input signal 553 based on the positive input signal 557 and the control signal, e.g., from controller 150 (FIG. 1).

In some demonstrative aspects, as shown in FIG. 5B, the first LS 523 may include a cross-coupling connection 543 to cross-couple the first LS circuitry 541 of the first LS 523 and the second LS circuitry 542 of the first LS 523.

In some demonstrative aspects, as shown in FIG. 5B, the first LS circuitry 541 of the first LS 523 may include a plurality of transistors 546 connected, e.g., in series, between a VDD and a VSS.

In some demonstrative aspects, as shown in FIG. 5B, the first LS circuitry 541 of the first LS 523 may include an input node 547 to input the first input signal 552, for example, to drive the plurality of transistors 546, for example, to generate the first single-ended LS output 572.

In some demonstrative aspects, as shown in FIG. 5B, the cross-coupling connection 543 of the first LS 523 may be configured to couple the second-LS-circuitry input signal 553 from the second LS circuitry 542 of the first LS 523 to a transistor node 549, which may be between first and second transistors in the plurality of transistors 546.

In some demonstrative aspects, as shown in FIG. 5B, the second LS circuitry 542 of the first LS 523 may include a plurality of transistors 556 connected, e.g., in series, between a VDD and a VSS.

In some demonstrative aspects, as shown in FIG. 5B, the second LS circuitry 542 of the first LS 523 may include an input node 557 to input the second-LS-circuitry input signal 553 to drive the plurality of transistors 556.

In some demonstrative aspects, as shown in FIG. 5B, the cross-coupling connection 543 of the first LS 523 may be configured to couple the first input signal 552 from the first LS circuitry 541 of the first LS 523 to a transistor node 539 between first and second transistors in the plurality of transistors 556.

In some demonstrative aspects, as shown in FIG. 5C, the second LS 525 may include first LS circuitry 561 to provide the second single-ended LS output 574, for example, based on the second input signal 554.

In some demonstrative aspects, as shown in FIG. 5C, the second LS 525 may include second LS circuitry 562 to receive a second-LS-circuitry input signal 555.

In some demonstrative aspects, as shown in FIG. 5C, the second-LS-circuitry input signal 555 may be based, for example, on the negative input signal 551.

In some demonstrative aspects, as shown in FIG. 5C, the second-LS-circuitry input signal 555 may be, for example, opposite to the second input signal 554.

In some demonstrative aspects, as shown in FIG. 5C, the single-mode DPA with the dual LS may include a second logical NOR gate 597, which may be configured to generate the second-LS-circuitry input signal 555 based on the negative input signal 551 and the control signal, e.g., from controller 150 (FIG. 1).

In some demonstrative aspects, as shown in FIG. 5C, the second LS 525 may include a cross-coupling connection 533 to cross-couple the first LS circuitry 561 of the second LS 525 and the second LS circuitry 562 of the second LS 525.

In some demonstrative aspects, as shown in FIG. 5C, the first LS circuitry 561 of the second LS 525 may include a plurality of transistors 566 connected, e.g., in series, between a VDD and a VSS.

In some demonstrative aspects, as shown in FIG. 5C, the first LS circuitry 561 of the second LS 525 may include an input node 567 to input the second input signal 554 to drive the plurality of transistors 566, for example, to generate the second single-ended LS output 574.

In some demonstrative aspects, as shown in FIG. 5C, the cross-coupling connection 533 of the second LS 525 may be configured to couple the second-LS-circuitry input signal 555 from the second LS circuitry 562 of the second LS 525 to a transistor node 569 between first and second transistors in the plurality of transistors 566.

In some demonstrative aspects, as shown in FIG. 5C, the second LS circuitry 562 of the second LS 525 may include a plurality of transistors 576 connected, e.g., in series, between a VDD and a VSS.

In some demonstrative aspects, as shown in FIG. 5C, the second LS circuitry 562 of the second LS 525 may include an input node 577 to input the second-LS-circuitry input signal 555, for example, to drive the plurality of transistors 576.

In some demonstrative aspects, as shown in FIG. 5C, the cross-coupling connection 533 of the second LS 525 may be configured to couple the second input signal 554 from the first LS circuitry 561 of the second LS 525 to a transistor node 579 between first and second transistors in the plurality of transistors 576.

In some demonstrative aspects, as shown in FIG. 5B, the first LS output 572 may include a first LS output signal 517 and a second LS output signal 518.

In some demonstrative aspects, as shown in FIG. 5C, the second LS output 574 may include a third LS output signal 537 and a fourth LS output signal 538.

In some demonstrative aspects, as shown in FIGS. 5A and 5D, the dual LS may be configured to generate the first LS output signal 517 to be equal to the third LS output signal 537, and the second LS output signal 518 to be equal to the fourth LS output signal 538, for example, based on a Low-Voltage (LV) setting of the first input signal 552 and the second input signal 554.

In some demonstrative aspects, the LV settings of the first input signal 552 and the second input signal 554 may correspond to an LV mode of the dual mode DPA.

In some demonstrative aspects, as shown in FIG. 5A and FIG. 5D, the dual LS 520 may be configured to generate the first LS output signal 517 and the third LS output signal 537 to include the VDD, and the second LS output signal 518 and the fourth LS output signal 538 to include the logic “1” voltage, for example, based on the LV setting of the first input signal 552 and the second input signal 554.

In some demonstrative aspects, as shown in FIG. 5B and FIG. 5C, the LV setting of the first input signal 552 and the second input signal 554 may include, for example, a setting of the first input signal 552 to be equal to a setting of the second input signal 554.

In some demonstrative aspects, as shown in FIG. 5B and FIG. 5C, the LV setting of the first input signal 552 and the second input signal 554 may include a setting of the first input signal 552 and the second input signal 554 to the logic “1” voltage.

In some demonstrative aspects, as shown in FIG. 5A and FIG. 5D, the dual LS 520 may be configured to generate the first LS output 572 to be different from the second LS output 574, for example, based on an a High-Voltage (HV) setting of the first input signal 552 and the second input signal 554.

In some demonstrative aspects, the HV setting of the first input signal 552 and the second input signal 554 may correspond to an HV mode of the dual-mode DPA.

In some demonstrative aspects, as shown in FIG. 5A and FIG. 5D, the first LS output 572 may include a clk_n signal, and the second LS output 574 may include a clk_p signal, e.g., at the high-voltage mode of the dual-mode DPA.

In some demonstrative aspects, as shown in FIG. 5B and FIG. 5C, the HV setting of the first input signal 552 and the second input signal 554 may include a setting of the first input signal 552 to be different from a setting of the second input signal 554.

In some demonstrative aspects, as shown in FIG. 5B and FIG. 5C, the HV setting of the first input signal 552 and the second input signal 554 may include a setting of the first input signal 552 to include the negative input signal 551, e.g., including an LO_n signal, and a setting of the second input signal 554 to include the positive input signal 557, e.g., including an LO_p signal.

In some demonstrative aspects, as shown in FIG. 5A, first PA circuitry 562 may include a first input node 511, which may be connected to a first output node, e.g., output node 113 (FIG. 1), of the first LS 523, e.g., to receive the first LS output signal 517.

In some demonstrative aspects, as shown in FIG. 5A, first PA circuitry 562 may include a second input node 512 connected to a second output node, e.g., output node 114 (FIG. 1), of the first LS 523 e.g., to receive the second LS output signal 518.

In some demonstrative aspects, as shown in FIG. 5A, first PA circuitry 562 may include a PA output node 515 to provide the first PA signal 563.

In some demonstrative aspects, as shown in FIG. 5D, second PA circuitry 564 may include a first input node 531 connected to a first output node of the second LS 525, e.g., output node 133 (FIG. 1), e.g., to receive the third LS output signal 537.

In some demonstrative aspects, as shown in FIG. 5D, second PA circuitry 564 may include a second input node 532 connected to a second output node e.g., output node 134 (FIG. 1), of the second LS 525, e.g., to receive the fourth LS output signal 538.

In some demonstrative aspects, as shown in FIG. 5D, second PA circuitry 564 may include a PA output node 535 to provide the second PA signal 565.

In some demonstrative aspects, the first PA circuitry 562 and/or the second PA circuitry 564 may include, for example, one or more, e.g., some or all, components and/or elements, of the PA circuitry 580 (FIG. 5E).

In some demonstrative aspects, PA circuitry 580 may be connected to an LS, e.g., LS 523 (FIG. 5B) or LS 525 (FIG. 5C).

In some demonstrative aspects, FIG. 5E may depict the PA circuitry 580 at the HV mode.

In some demonstrative aspects, FIG. 5F may depict the PA circuitry 580 at the LV mode.

In some demonstrative aspects, as shown in FIG. 5E, PA circuitry 580 may include a first input node 581, which may be connected to a first output node of the LS. For example, first input node 581 may be connected to output node 113 (FIG. 1) of LS 523 (FIG. 5B), e.g., in case PA circuitry 580 is implemented as part of PA circuitry 562 (FIG. 5A). For example, first input node 581 may be connected to output node 133 (FIG. 1) of LS 525 (FIG. 5C), e.g., in case PA circuitry 580 is implemented as part of PA circuitry 564 (FIG. 5D).

In some demonstrative aspects, as shown in FIG. 5E, PA circuitry 580 may include a second input node 582, which may be connected to a second output node of the LS. For example, second input node 582 may be connected to output node 114 (FIG. 1) of LS 523 (FIG. 5B), e.g., in case PA circuitry 580 is implemented as part of PA circuitry 562 (FIG. 5A). For example, second input node 582 may be connected to output node 134 (FIG. 1) of LS 525 (FIG. 5C), e.g., in case PA circuitry 580 is implemented as part of PA circuitry 564 (FIG. 5D).

In some demonstrative aspects, as shown in FIG. 5E, PA circuitry 580 may include a PA output node 583 to provide a PA signal 585. For example, PA output node 515 (FIG. 5A) may include PA output node 583, e.g., in case PA circuitry 580 is implemented as part of PA circuitry 562 (FIG. 5A). For example, PA output node 535 (FIG. 5D) may include PA output node 583, e.g., in case PA circuitry 580 is implemented as part of PA circuitry 564 (FIG. 5D).

In some demonstrative aspects, as shown in FIG. 5E, PA circuitry 580 may include a first plurality of transistors 584 connected in series between a VDD and the PA output node 583.

In some demonstrative aspects, as shown in FIG. 5E, a gate of a transistor of the first plurality of transistors 584 may be connected to the first input node 581.

In some demonstrative aspects, as shown in FIG. 5E, PA circuitry 580 may include a second plurality of transistors 586 connected in series between a VSS and the PA output node 583.

In some demonstrative aspects, as shown in FIG. 5E, a gate of a transistor of the second plurality of transistors 586 may be connected to the second input node 582.

In some demonstrative aspects, as shown in FIG. 5E, the VDD may be equal to 3xVd,max, which may be at least three times the VSS.

In some demonstrative aspects, as shown in FIG. 5B and FIG. 5C, the differential input signal 559 may be in a voltage domain of a VDD region.

In some demonstrative aspects, as shown in FIG. 5A and FIG. 5D, the first PA signal 563 and the second PA signal 565 may be, for example, in a second voltage domain of a 3xVDD region.

In some demonstrative aspects, a dual-LS mechanism may be implemented for a PA cell utilizing a 3-stacking structure including a 6-device structure, e.g., as described above.

In other aspects, the dual-LS mechanism may be implemented for any other PA cell utilizing any other stacking structure and/or any other PA structure and/or architecture.

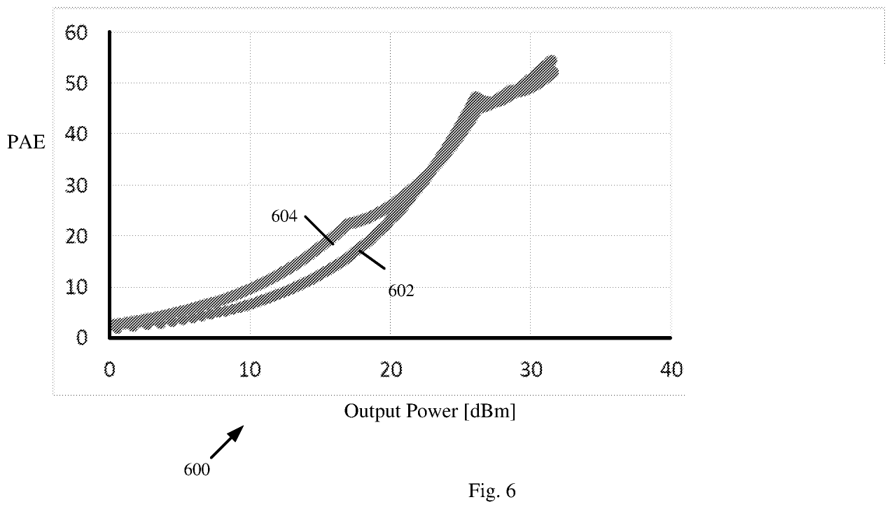

Reference is made to FIG. 6, which schematically illustrates a graph 600 depicting simulated Power Added Efficiency (PAE) results versus output power, in accordance with some demonstrative aspects.

For example, as shown in FIG. 6, a first curve 602 illustrates the simulated PAE results for an implementation of a single mode DPA.

For example, as shown in FIG. 6, a second graph 604 illustrates the simulated PAE results for an implementation of a dual mode DPA utilizing a dual LS.

As shown in FIG. 6, implementation of the dual mode DPA utilizing the dual LS may provide a technical solution to achieve improved efficiency, e.g., in higher back-off (lower output power).

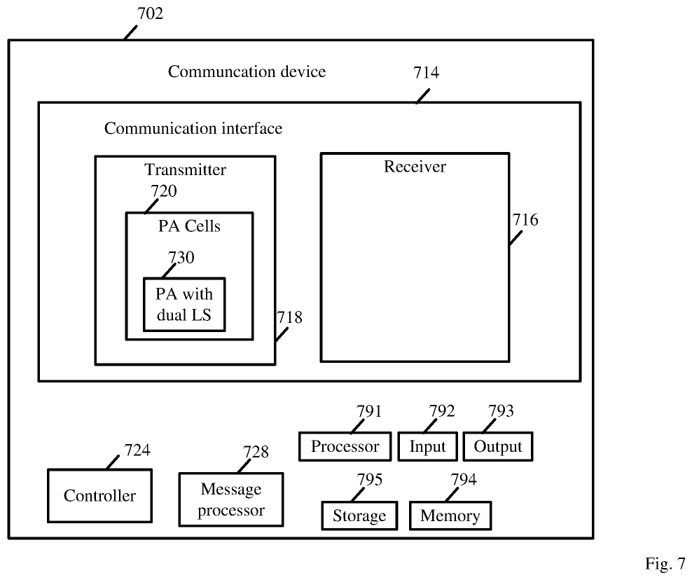

Reference is now made to FIG. 7, which schematically illustrates a block diagram of a communication device 702, in accordance with some demonstrative aspects.

In some demonstrative aspects, communication device 702 may include a wireless communication device, and/or a wired communication device.

In some demonstrative aspects, communication device 702 may include, for example, a computing device, an MD, a STA, a PC, a desktop computer, a mobile computer, a laptop computer, an Ultrabook™ computer, a Smartphone, a gaming device, a peripheral device, a notebook computer, a tablet computer, a handheld computer, an Internet of Things (IoT) device, a sensor device, a handheld device, a wearable device, an on-board device, an off-board device, a consumer device, a vehicular device, a non-vehicular device, a mobile or portable device, a non-mobile or non-portable device, a mobile phone, a cellular telephone, a video device, an audio device, an A/V device, a video source, an audio source, a video sink, an audio sink, a Personal Media Player (PMP), a digital audio player, a data source, a data sink, a media player, or the like.

In some demonstrative aspects, communication device 702 may include, operate as, and/or perform the functionality of, a WLAN STA.

In some demonstrative aspects, communication device 702 may include, operate as, and/or perform the functionality of, a Wi-Fi STA.

In some demonstrative aspects, communication device 702 may include, operate as, and/or perform the functionality of, a BT device.

In some demonstrative aspects, communication device 702 may include, operate as, and/or perform the functionality of, one or more cellular client devices.

In other aspects, communication device 702 may include, operate as, and/or perform the functionality of any other type communication device, and/or any other device.

In some demonstrative aspects, communication device 702 may include, for example, one or more of a processor 791, an input unit 792, an output unit 793, a memory unit 794, and/or a storage unit 795. Communication device 702 may optionally include other suitable hardware components and/or software components. In some demonstrative aspects, some or all of the components of communication device 702 may be enclosed in a common housing or packaging, and may be interconnected or operably associated using one or more wired or wireless links. In other aspects, components of communication device 702 may be distributed among multiple or separate devices.

In some demonstrative aspects, processor 791 may include, for example, a Central Processing Unit (CPU), a Digital Signal Processor (DSP), one or more processor cores, a single-core processor, a dual-core processor, a multiple-core processor, a microprocessor, a host processor, a controller, a plurality of processors or controllers, a chip, a microchip, one or more circuits, circuitry, a logic unit, an Integrated Circuit (IC), an Application-Specific IC (ASIC), or any other suitable multi-purpose or specific processor or controller. Processor 791 executes instructions, for example, of an Operating System (OS) of communication device 702 and/or of one or more suitable applications.

In some demonstrative aspects, input unit 792 may include, for example, a keyboard, a keypad, a mouse, a touch-screen, a touch-pad, a track-ball, a stylus, a microphone, or other suitable pointing device or input device. Output unit 793 includes, for example, a screen, a touch-screen, a flat panel display, a Light Emitting Diode (LED) display unit, a Liquid Crystal Display (LCD) display unit, a plasma display unit, one or more audio speakers or earphones, or other suitable output devices.

In some demonstrative aspects, memory unit 794 includes, for example, a Random Access Memory (RAM), a Read Only Memory (ROM), a Dynamic RAM (DRAM), a Synchronous DRAM (SD-RAM), a flash memory, a volatile memory, a non-volatile memory, a cache memory, a buffer, a short term memory unit, a long term memory unit, or other suitable memory units. Storage unit 795 includes, for example, a hard disk drive, a Solid State Drive (SSD), and/or other suitable removable or non-removable storage units. Memory unit 794 and/or storage unit 795, for example, may store data processed by communication device 702.

In some demonstrative aspects, communication device 702 may be capable of communicating content, data, information and/or signals via a communication medium, e.g., a wireless medium or a wired medium.

In some demonstrative aspects, the wireless medium may include, for example, a radio channel, a cellular channel, an RF channel, a WiFi channel, a BT channel, an IR channel, and the like.

In some demonstrative aspects, communication device 702 may include one or more radios and or communication interfaces including circuitry and/or logic to perform communication between communication device 702 and/or one or more other devices. For example, communication device 702 may include at least one communication interface 714.

In some demonstrative aspects, communication interface 714 may include, for example, a WiFi radio, a cellular radio, a BT radio, and/or the like.

In some demonstrative aspects, communication interface 714 may include one or more receivers (Rx) including circuitry and/or logic to receive wireless communication signals, RF signals, frames, blocks, transmission streams, packets, messages, data items, and/or data. For example, communication interface 714 may include at least one receiver 716.

In some demonstrative aspects, communication interface 714 may include one or more transmitters (Tx) including circuitry and/or logic to transmit wireless communication signals, RF signals, frames, blocks, transmission streams, packets, messages, data items, and/or data. For example, communication interface 714 may include at least one transmitter 718.

In some demonstrative aspects, communication interface 714, transmitter 718, and/or receiver 716 may include circuitry; logic; Radio Frequency (RF) elements, circuitry and/or logic; baseband elements, circuitry and/or logic; modulation elements, circuitry and/or logic; demodulation elements, circuitry and/or logic; amplifiers; analog to digital and/or digital to analog converters; filters; and/or the like.

In some demonstrative aspects, transmitter 718 may include a plurality of PA cells 720, which may be configured to amplify an input signal to be transmitted to one or more other communication devices.

In some demonstrative aspects, a PA cell 720, e.g., each PA cell 720, may include a dual-LS PA 730. For example, dual-LS PA 730 may include one or more elements of dual-LS DPA 110 (FIG. 1) and/or may perform one or more operations of dual-LS DPA 110 (FIG. 1).

In some demonstrative aspects, dual-LS PA 730 may include a single-mode PA, e.g., as described above.

In some demonstrative aspects, dual-LS PA 730 may include a dual-mode PA, which may be operable at a plurality of power modes, for example, to provide output signals in a plurality of voltage domains, e.g., as described above.

In some demonstrative aspects, dual-LS PA 730 may be operable at a first power mode to provide an output signal in a first voltage domain, e.g., configured for a first communication technology. For example, the first voltage domain may be configured for BT communication according to a BT technology.

In some demonstrative aspects, dual-LS PA 730 may be operable at a second power mode to provide an output signal in a second voltage domain, e.g., configured for a second communication technology. For example, the second voltage domain may be configured for WLAN, e.g., WiFi, communication according to a WLAN, e.g., WiFi, technology.

In some demonstrative aspects, the PA cells 720 may be implemented as part of circuitry supporting both the first communication technology and the second communication technology, e.g., in a same core.

In some demonstrative aspects, communication device 702 may include a controller 724 configured to perform and/or to trigger, cause, instruct and/or control communication device 702 to perform, one or more communications, to generate and/or communicate one or more messages and/or transmissions, and/or to perform one or more functionalities, operations and/or procedures between communication device 702 and/or one or more other devices, e.g., as described below. For example, controller 724 may include one or more elements controller 150 (FIG. 1), and/or may perform one or more operations of controller 150 (FIG. 1).

In some demonstrative aspects, controller 724 may include, or may be implemented, partially or entirely, by circuitry and/or logic, e.g., one or more processors including circuitry and/or logic, memory circuitry and/or logic, Media-Access Control (MAC) circuitry and/or logic, Physical Layer (PHY) circuitry and/or logic, baseband (BB) circuitry and/or logic, a BB processor, a BB memory, Application Processor (AP) circuitry and/or logic, an AP processor, an AP memory, and/or any other circuitry and/or logic, configured to perform the functionality of controller 724. Additionally or alternatively, one or more functionalities of controller 724 may be implemented by logic, which may be executed by a machine and/or one or more processors, e.g., as described below.

In one example, controller 724 may include circuitry and/or logic, for example, one or more processors including circuitry and/or logic, to cause, trigger and/or control a communication device 702, e.g., communication device 702, to perform one or more operations, communications and/or functionalities, e.g., as described herein. In one example, controller 724 may include at least one memory, e.g., coupled to the one or more processors, which may be configured, for example, to store, e.g., at least temporarily, at least some of the information processed by the one or more processors and/or circuitry, and/or which may be configured to store logic to be utilized by the processors and/or circuitry.

In some demonstrative aspects, device 702 may include a message processor 728 configured to generate, process and/or access one or more messages communicated by device 702.

In one example, message processor 728 may be configured to generate one or more messages to be transmitted by device 702, and/or message processor 728 may be configured to access and/or to process one or more messages received by device 702, e.g., as described below.

In some demonstrative aspects, message processor 728 may include, or may be implemented, partially or entirely, by circuitry and/or logic, e.g., one or more processors including circuitry and/or logic, memory circuitry and/or logic. Additionally or alternatively, one or more functionalities of message processor 728 may be implemented by logic, which may be executed by a machine and/or one or more processors, e.g., as described below.

In some demonstrative aspects, at least part of the functionality of message processor 728 may be implemented as part of controller 724.

In other aspects, the functionality of message processor 728 may be implemented as part of any other element of device 702.

In some demonstrative aspects, at least part of the functionality of communication interface 714, controller 724, and/or message processor 728 may be implemented by an integrated circuit, for example, a chip, e.g., a System on Chip (SoC). In one example, the chip or SoC may be configured to perform one or more functionalities of one or more functionalities of communication interface 714, controller 724, and one or more functionalities of message processor 728. In one example, communication interface 714, controller 724 and message processor 728 may be implemented as part of the chip or SoC.

In other aspects, communication interface 714, controller 724 and/or message processor 728 may be implemented by one or more additional or alternative elements of communication device 702.

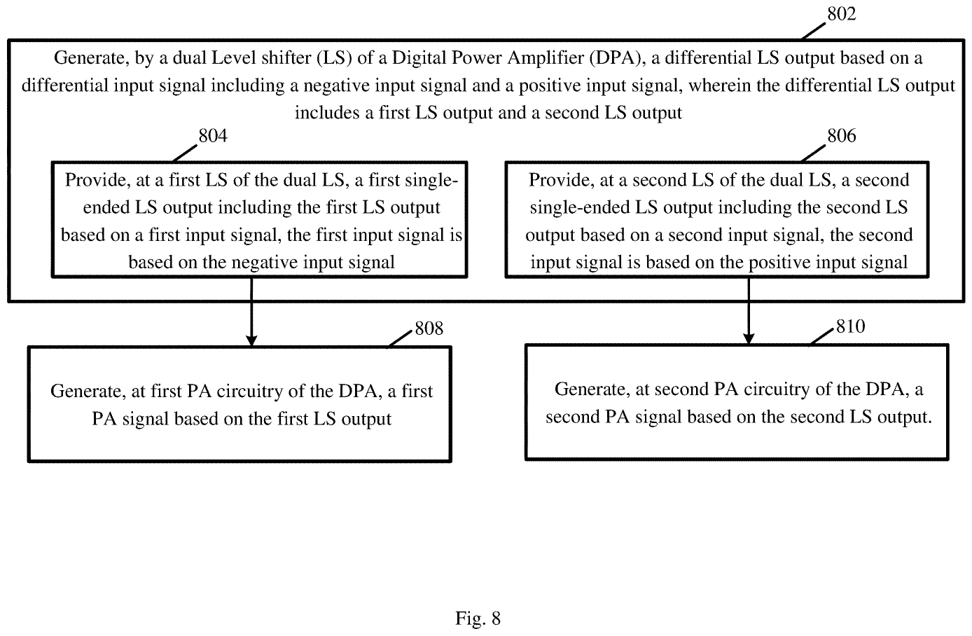

Reference is made to FIG. 8, which schematically illustrates a method of a DPA. For example, one or more operations of the method of FIG. 8 may be performed by a DPA, e.g., DPA 110 (FIG. 1); and/or a communication device, e.g., device 702 (FIG. 7).

In some demonstrative aspects, as indicated at block 802, the method may include generating, by a dual LS of a DPA, a differential LS output based on a differential input signal including a negative input signal and a positive input signal. For example, the differential LS output may include a first LS output and a second LS output. For example, dual-LS 120 (FIG. 1) may generate the differential LS output based on the differential input signal 159 (FIG. 1) including the negative input signal 151 (FIG. 1) and the positive input signal 157 (FIG. 1), e.g., as descried above.

In some demonstrative aspects, as indicated at block 804, generating the differential LS output may include providing, at a first LS of the dual LS, a first single-ended LS output including the first LS output based on a first input signal. For example, the first input signal may be based on the negative input signal. For example, first LS 123 (FIG. 1) may generate the first single-ended LS output including the first LS output 172 (FIG. 1) based on the first input signal 152 (FIG. 1), e.g., as descried above.

In some demonstrative aspects, as indicated at block 806, generating the differential LS output may include providing, at a second LS of the dual LS, a second single-ended LS output including the second LS output based on a second input signal. For example, the second input signal may be based on the positive input signal. For example, second LS 125 (FIG. 1) may generate the second single-ended LS output including the second LS output 174 (FIG. 1) based on the second input signal 154 (FIG. 1), e.g., as descried above.

In some demonstrative aspects, as indicated at block 808, the method may include generating, at first PA circuitry of the DPA, a first PA signal based on the first LS output. For example, first PA circuitry 162 (FIG. 1) may generate the first PA signal 163 (FIG. 1), for example, based on the first LS output 172 (FIG. 1), e.g., as descried above.

In some demonstrative aspects, as indicated at block 810, the method may include generating, at second PA circuitry of the DPA, a second PA signal based on the second LS output. For example, second PA circuitry 164 (FIG. 1) may generate the second PA signal 165 (FIG. 1), for example, based on the second LS output 174 (FIG. 1), e.g., as descried above.

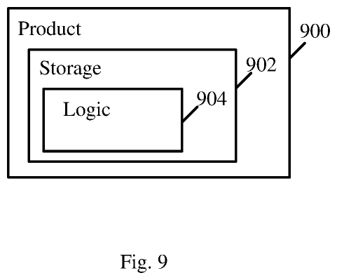

Reference is made to FIG. 9, which schematically illustrates a product of manufacture 900, in accordance with some demonstrative aspects. Product 900 may include one or more tangible computer-readable (“machine-readable”) non-transitory storage media 902, which may include computer-executable instructions, e.g., implemented by logic 904, operable to, when executed by at least one computer processor, enable the at least one computer processor to implement one or more operations at device 702 (FIG. 7), and/or DPA 110 (FIG. 1); to cause device 702 (FIG. 7), and/or DPA 110 (FIG. 1) to perform, trigger and/or implement one or more operations and/or functionalities; and/or to perform, trigger and/or implement one or more operations and/or functionalities described with reference to the FIGS. 1-8, and/or one or more operations described herein. The phrases “non-transitory machine-readable medium” and “computer-readable non-transitory storage media” may be directed to include all machine and/or computer readable media, with the sole exception being a transitory propagating signal.

In some demonstrative aspects, product 900 and/or machine-readable storage media 902 may include one or more types of computer-readable storage media capable of storing data, including volatile memory, non-volatile memory, removable or non-removable memory, erasable or non-erasable memory, writeable or re-writeable memory, and the like. For example, machine-readable storage media 902 may include, RAM, DRAM, Double-Data-Rate DRAM (DDR-DRAM), SDRAM, static RAM (SRAM), ROM, programmable ROM (PROM), erasable programmable ROM (EPROM), electrically erasable programmable ROM (EEPROM), flash memory (e.g., NOR or NAND flash memory), content addressable memory (CAM), polymer memory, phase-change memory, ferroelectric memory, silicon-oxide-nitride-oxide-silicon (SONOS) memory, a disk, a hard drive, and the like. The computer-readable storage media may include any suitable media involved with downloading or transferring a computer program from a remote computer to a requesting computer carried by data signals embodied in a carrier wave or other propagation medium through a communication link, e.g., a modem, radio or network connection.

In some demonstrative aspects, logic 904 may include instructions, data, and/or code, which, if executed by a machine, may cause the machine to perform a method, process and/or operations as described herein. The machine may include, for example, any suitable processing platform, computing platform, computing device, processing device, computing system, processing system, computer, processor, or the like, and may be implemented using any suitable combination of hardware, software, firmware, and the like.

In some demonstrative aspects, logic 904 may include, or may be implemented as, software, a software module, an application, a program, a subroutine, instructions, an instruction set, computing code, words, values, symbols, and the like. The instructions may include any suitable type of code, such as source code, compiled code, interpreted code, executable code, static code, dynamic code, and the like. The instructions may be implemented according to a predefined computer language, manner or syntax, for instructing a processor to perform a certain function. The instructions may be implemented using any suitable high-level, low-level, object-oriented, visual, compiled and/or interpreted programming language, machine code, and the like.

### EXAMPLES

The following examples pertain to further aspects.

Example 1 includes an apparatus comprising a Digital Power Amplifier (PA) (DPA) comprising a dual Level Shifter (LS) configured to generate a differential LS output based on a differential input signal comprising a negative input signal and a positive input signal, wherein the differential LS output comprises a first LS output and a second LS output, wherein the dual LS comprises a first LS to provide a first single-ended LS output comprising the first LS output based on a first input signal, the first input signal is based on the negative input signal; and a second LS to provide a second single-ended LS output comprising the second LS output based on a second input signal, the second input signal is based on the positive input signal; first PA circuitry configured to generate a first PA signal based on the first LS output; and second PA circuitry configured to generate a second PA signal based on the second LS output.

Example 2 includes the subject matter of Example 1, and optionally, wherein the first LS comprises first LS circuitry to provide the first single-ended LS output based on the first input signal; second LS circuitry to receive a second-LS-circuitry input signal, wherein the second-LS-circuitry input signal is based on the positive input signal; and a cross-coupling connection to cross-couple the first LS circuitry of the first LS and the second LS circuitry of the first LS.

Example 3 includes the subject matter of Example 2, and optionally, wherein the first LS circuitry of the first LS comprises a plurality of transistors connected between a Drain Voltage (VDD) and a Supply Voltage (VSS), and an input node to input the first input signal to drive the plurality of transistors of the first LS circuitry of the first LS to generate the first single-ended LS output.

Example 4 includes the subject matter of Example 3, and optionally, wherein the cross-coupling connection of the first LS is configured to couple the second-LS-circuitry input signal from the second LS circuitry of the first LS to a transistor node between first and second transistors in the plurality of transistors of the first LS circuitry of the first LS.

Example 5 includes the subject matter of any one of Examples 2-4, and optionally, wherein the second LS circuitry of the first LS comprises a plurality of transistors connected between a Drain Voltage (VDD) and a Supply Voltage (VSS), and an input node to input the second-LS-circuitry input signal to drive the plurality of transistors of the second LS circuitry of the first LS.

Example 6 includes the subject matter of Example 5, and optionally, wherein the cross-coupling connection of the first LS is to couple the first input signal from the first LS circuitry of the first LS to a transistor node between first and second transistors in the plurality of transistors of the second LS circuitry of the first LS.

Example 7 includes the subject matter of any one of Examples 2-6, and optionally, wherein the second-LS-circuitry input signal is opposite to the first input signal.

Example 8 includes the subject matter of any one of Examples 1-7, and optionally, wherein the second LS comprises first LS circuitry to provide the second single-ended LS output based on the second input signal; second LS circuitry to receive a second-LS-circuitry input signal, wherein the second-LS-circuitry input signal is based on the negative input signal; and a cross-coupling connection to cross-couple the first LS circuitry of the second LS and the second LS circuitry of the second LS.

Example 9 includes the subject matter of Example 8, and optionally, wherein the first LS circuitry of the second LS comprises a plurality of transistors connected between a Drain Voltage (VDD) and a Supply Voltage (VSS), and an input node to input the second input signal to drive the plurality of transistors of the first LS circuitry of the second LS to generate the second single-ended LS output.

Example 10 includes the subject matter of Example 9, and optionally, wherein the cross-coupling connection of the second LS is to couple the second-LS-circuitry input signal from the second LS circuitry of the second LS to a transistor node between first and second transistors in the plurality of transistors of the first LS circuitry of the second LS.

Example 11 includes the subject matter of any one of Examples 8-10, and optionally, wherein the second LS circuitry of the second LS comprises a plurality of transistors connected between a Drain Voltage (VDD) and a Supply Voltage (VSS), and an input node to input the second-LS-circuitry input signal to drive the plurality of transistors of the second LS circuitry of the second LS.

Example 12 includes the subject matter of Example 11, and optionally, wherein the cross-coupling connection of the second LS is to couple the second input signal from the first LS circuitry of the second LS to a transistor node between first and second transistors in the plurality of transistors of the second LS circuitry of the second LS.

Example 13 includes the subject matter of any one of Examples 8-12, and optionally, wherein the second-LS-circuitry input signal is opposite to the second input signal.

Example 14 includes the subject matter of any one of Examples 1-13, and optionally, wherein the dual LS is configured to generate the first LS output to be equal to the second LS output based on a particular setting of the first input signal and the second input signal.

Example 15 includes the subject matter of Example 14, and optionally, wherein the first LS output comprises a first LS output signal and a second LS output signal, wherein the second LS output comprises a third LS output signal and a fourth LS output signal, wherein the dual LS is configured to, based on the particular setting of the first input signal and the second input signal, generate the first LS output signal to be equal to the third LS output signal, and the second LS output signal to be equal to the fourth LS output signal.

Example 16 includes the subject matter of Example 15, and optionally, wherein the dual LS is configured to, based on the particular setting of the first input signal and the second input signal, generate the first LS output signal and the third LS output signal comprising a Drain Voltage (VDD), and the second LS output signal and the fourth LS output signal comprising a logic “1” voltage.

Example 17 includes the subject matter of Example 16, and optionally, wherein the VDD is at least 2 times the logic “1” voltage.

Example 18 includes the subject matter of any one of Examples 14-17, and optionally, wherein the particular setting of the first input signal and the second input signal comprises a setting of the first input signal equal to a setting of the second input signal.

Example 19 includes the subject matter of any one of Examples 14-18, and optionally, wherein the particular setting of the first input signal and the second input signal comprises a setting of the first input signal and the second input signal to a logic “1” voltage.

Example 20 includes the subject matter of any one of Examples 14-19, and optionally, wherein the dual LS is configured to generate the first LS output to be different from the second LS output based on an other setting of the first input signal and the second input signal.

Example 21 includes the subject matter of Example 20, and optionally, wherein the particular setting of the first input signal and the second input signal corresponds to a first state of the DPA, wherein the other setting of the first input signal and the second input signal corresponds to a second state of the DPA.

Example 22 includes the subject matter of Example 20 or 21, and optionally, wherein the other setting of the first input signal and the second input signal comprises a setting of the first input signal different from a setting of the second input signal.

Example 23 includes the subject matter of any one of Examples 20-22, and optionally, wherein the other setting of the first input signal and the second input signal comprises a setting of the first input signal to comprise the negative input signal and a setting of the second input signal to comprise the positive input signal.

Example 24 includes the subject matter of any one of Examples 20-23, and optionally, wherein the particular setting of the first input signal and the second input signal corresponds to an off-state of the DPA, wherein the other setting of the first input signal and the second input signal corresponds to an on-state of the DPA.

Example 25 includes the subject matter of any one of Examples 20-23, and optionally, wherein the particular setting of the first input signal and the second input signal corresponds to a first power mode of the DPA, wherein the other setting of the first input signal and the second input signal corresponds to a second power mode of the DPA.

Example 26 includes the subject matter of any one of Examples 1-25, and optionally, comprising a controller configured to control a state of the DPA, and to control a setting of the first input signal and a setting of the second input signal according to the state of the DPA.

Example 27 includes the subject matter of any one of Examples 1-26, and optionally, wherein the first PA circuitry comprises a first input node connected to a first output node of the first LS; a second input node connected to a second output node of the first LS; a PA output node to provide the first PA signal; a first plurality of transistors connected in series between a first PA voltage and the PA output node, wherein a gate of a transistor of the first plurality of transistors is connected to the first input node; and a second plurality of transistors connected in series between a second PA voltage and the PA output node, wherein a gate of a transistor of the second plurality of transistors is connected to the second input node.

Example 28 includes the subject matter of Example 27, and optionally, wherein the first PA voltage is at least two times the second PA voltage.

Example 29 includes the subject matter of any one of Examples 1-28, and optionally, wherein the second PA circuitry comprises a first input node connected to a first output node of the second LS; a second input node connected to a second output node of the second LS; a PA output node to provide the second PA signal; a first plurality of transistors connected in series between a first PA voltage and the PA output node, wherein a gate of a transistor of the first plurality of transistors is connected to the first input node; and a second plurality of transistors connected in series between a second PA voltage and the PA output node, wherein a gate of a transistor of the second plurality of transistors is connected to the second input node.

Example 30 includes the subject matter of Example 29, and optionally, wherein the first PA voltage is at least two times the second PA voltage.

Example 31 includes the subject matter of any one of Examples 1-30, and optionally, wherein the differential input signal is in a first voltage domain, wherein the first PA signal and the second PA signal are in a second voltage domain, wherein a maximal voltage of the second voltage domain is at least two times a maximal voltage of the first voltage domain.

Example 32 includes the subject matter of Example 31, and optionally, wherein the maximal voltage of the second voltage domain is at least three times the maximal voltage of the first voltage domain.

Example 33 includes the subject matter of any one of Examples 1-32, and optionally, wherein the DPA comprises a multi-mode DPA switchable between a plurality of power modes to generate a DPA output signal based on the differential input signal in a first voltage domain, wherein the multi-mode DPA is configured to provide the DPA output signal in the first voltage domain at a first power mode, and to provide the DPA output signal in a second voltage domain at a second power mode.

Example 34 includes the subject matter of any one of Examples 1-33, and optionally, wherein the DPA comprises a single-mode DPA.

Example 35 includes the subject matter of any one of Examples 1-34, and optionally, comprising a transmitter to transmit wireless communication signals, the transmitter comprising the DPA.

Example 36 includes a wireless communication device comprising a processor to process data; one or more antennas; and a transmitter to transmit wireless communication signals via the one or more antennas based on the data, wherein the transmitter comprises the apparatus according to any of Examples 1-35.

Example 37 comprises a wireless communication device comprising the apparatus of any one of Examples 1-35.

Example 38 comprises an apparatus comprising means for executing any of the described operations of Examples 1-35.

Example 39 comprises a product comprising one or more tangible computer-readable non-transitory storage media comprising instructions operable to, when executed by at least one processor, enable the at least one processor to cause a device to perform any of the described operations of Examples 1-35.

Example 40 comprises an apparatus comprising: a memory interface; and processing circuitry configured to: perform any of the described operations of Examples 1-35.

Example 41 comprises a method comprising any of the described operations of Examples 1-35.

Functions, operations, components and/or features described herein with reference to one or more aspects, may be combined with, or may be utilized in combination with, one or more other functions, operations, components and/or features described herein with reference to one or more other aspects, or vice versa.

While certain features have been illustrated and described herein, many modifications, substitutions, changes, and equivalents may occur to those skilled in the art. It is, therefore, to be understood that the appended claims are intended to cover all such modifications and changes as fall within the true spirit of the disclosure.

1.-25. (canceled)

26. An apparatus comprising:
a Digital Power Amplifier (PA) (DPA) comprising:
a dual Level Shifter (LS) configured to generate a differential LS output based on a differential input signal comprising a negative input signal and a positive input signal, wherein the differential LS output comprises a first LS output and a second LS output, wherein the dual LS comprises:
a first LS to provide a first single-ended LS output comprising the first LS output based on a first input signal, the first input signal is based on the negative input signal; and
a second LS to provide a second single-ended LS output comprising the second LS output based on a second input signal, the second input signal is based on the positive input signal;
first PA circuitry configured to generate a first PA signal based on the first LS output; and
second PA circuitry configured to generate a second PA signal based on the second LS output.

27. The apparatus of claim 26, wherein the first LS comprises:
first LS circuitry to provide the first single-ended LS output based on the first input signal;
second LS circuitry to receive a second-LS-circuitry input signal, wherein the second-LS-circuitry input signal is based on the positive input signal; and
a cross-coupling connection to cross-couple the first LS circuitry of the first LS and the second LS circuitry of the first LS.

28. The apparatus of claim 27, wherein the first LS circuitry of the first LS comprises a plurality of transistors connected between a Drain Voltage (VDD) and a Supply Voltage (VSS), and an input node to input the first input signal to drive the plurality of transistors of the first LS circuitry of the first LS to generate the first single-ended LS output.

29. The apparatus of claim 28, wherein the cross-coupling connection of the first LS is configured to couple the second-LS-circuitry input signal from the second LS circuitry of the first LS to a transistor node between first and second transistors in the plurality of transistors of the first LS circuitry of the first LS.

30. The apparatus of claim 27, wherein the second LS circuitry of the first LS comprises a plurality of transistors connected between a Drain Voltage (VDD) and a Supply Voltage (VSS), and an input node to input the second-LS-circuitry input signal to drive the plurality of transistors of the second LS circuitry of the first LS.

31. The apparatus of claim 30, wherein the cross-coupling connection of the first LS is to couple the first input signal from the first LS circuitry of the first LS to a transistor node between first and second transistors in the plurality of transistors of the second LS circuitry of the first LS.

32. The apparatus of claim 26, wherein the second LS comprises:
first LS circuitry to provide the second single-ended LS output based on the second input signal;
second LS circuitry to receive a second-LS-circuitry input signal, wherein the second-LS-circuitry input signal is based on the negative input signal; and
a cross-coupling connection to cross-couple the first LS circuitry of the second LS and the second LS circuitry of the second LS.

33. The apparatus of claim 26, wherein the dual LS is configured to generate the first LS output to be equal to the second LS output based on a particular setting of the first input signal and the second input signal.

34. The apparatus of claim 33, wherein the first LS output comprises a first LS output signal and a second LS output signal, wherein the second LS output comprises a third LS output signal and a fourth LS output signal, wherein the dual LS is configured to, based on the particular setting of the first input signal and the second input signal, generate the first LS output signal to be equal to the third LS output signal, and the second LS output signal to be equal to the fourth LS output signal.

35. The apparatus of claim 34, wherein the dual LS is configured to, based on the particular setting of the first input signal and the second input signal, generate the first LS output signal and the third LS output signal comprising a Drain Voltage (VDD), and the second LS output signal and the fourth LS output signal comprising a logic “1” voltage.

36. The apparatus of claim 33, wherein the dual LS is configured to generate the first LS output to be different from the second LS output based on an other setting of the first input signal and the second input signal.

37. The apparatus of claim 36, wherein the particular setting of the first input signal and the second input signal corresponds to a first state of the DPA, wherein the other setting of the first input signal and the second input signal corresponds to a second state of the DPA.

38. The apparatus of claim 36, wherein the other setting of the first input signal and the second input signal comprises a setting of the first input signal different from a setting of the second input signal.

39. The apparatus of claim 36, wherein the other setting of the first input signal and the second input signal comprises a setting of the first input signal to comprise the negative input signal and a setting of the second input signal to comprise the positive input signal.

40. The apparatus of claim 36, wherein the particular setting of the first input signal and the second input signal corresponds to a first power mode of the DPA, wherein the other setting of the first input signal and the second input signal corresponds to a second power mode of the DPA.

41. The apparatus of claim 26 comprising a controller configured to control a state of the DPA, and to control a setting of the first input signal and a setting of the second input signal according to the state of the DPA.

42. The apparatus of claim 26, wherein the first PA circuitry comprises:
a first input node connected to a first output node of the first LS;
a second input node connected to a second output node of the first LS;
a PA output node to provide the first PA signal;
a first plurality of transistors connected in series between a first PA voltage and the PA output node, wherein a gate of a transistor of the first plurality of transistors is connected to the first input node; and
a second plurality of transistors connected in series between a second PA voltage and the PA output node, wherein a gate of a transistor of the second plurality of transistors is connected to the second input node.

43. The apparatus of claim 26 comprising a transmitter to transmit wireless communication signals, the transmitter comprising the DPA.

44. A wireless communication device comprising:
a processor to process data;
one or more antennas; and
a transmitter to transmit wireless communication signals via the one or more antennas based on the data, wherein the transmitter comprises:
a Digital Power Amplifier (PA) (DPA) comprising:
a dual Level Shifter (LS) configured to generate a differential LS output based on a differential input signal comprising a negative input signal and a positive input signal, wherein the differential LS output comprises a first LS output and a second LS output, wherein the dual LS comprises:
a first LS to provide a first single-ended LS output comprising the first LS output based on a first input signal, the first input signal is based on the negative input signal; and
a second LS to provide a second single-ended LS output comprising the second LS output based on a second input signal, the second input signal is based on the positive input signal;
first PA circuitry configured to generate a first PA signal based on the first LS output; and
second PA circuitry configured to generate a second PA signal based on the second LS output.

45. The wireless communication device of claim 44 comprising a controller configured to control a state of the DPA, and to control a setting of the first input signal and a setting of the second input signal according to the state of the DPA.
